(19) United States
(12) Patent Application Publication
(10) Pub. No.: US 2025/0048685 A1
(43) Pub. Date: Feb. 6, 2025

(54) SEMICONDUCTOR DEVICE

(71) Applicant: ROHM CO., LTD., Kyoto (JP)

(72) Inventor: Yuji OSUMI, Kyoto (JP)

(73) Assignee: ROHM CO., LTD., Kyoto (JP)

(21) Appl. No.: 18/792,449

(22) Filed: Aug. 1, 2024

(30) Foreign Application Priority Data
Aug. 4, 2023 (JP) 2023-127976

(51) Int. Cl. H01L 29/06; H01L 23/34; H01L 23/528; H01L 27/07; H01L 29/423; H01L 29/78; H01L 29/861

(52) U.S. Cl. CPC H01L 29/0623; H01L 23/34; H01L 23/5286; H01L 27/0705; H01L 29/42368; H01L 29/7813; H01L 29/7831; H01L 29/8611

(57) ABSTRACT

A semiconductor device includes: a semiconductor chip having a main surface; an output region formed over the main surface with output elements being arranged in the output region; an inner element region surrounded by the output region and insulated and isolated from the output region with a first element different from the output elements being arranged in the inner element region; a first wiring layer formed over the main surface so as to cover the output region, and including a first output wiring electrically connected to the output elements; and a second wiring layer formed over the first wiring layer, and including second output wirings electrically connected to the first output wiring and a connection wiring insulated and isolated from the second output wirings, the connection wiring extending across the output region from the inner element region to an outer region outside the output region.

### CROSS-REFERENCE TO RELATED APPLICATION

This application is based upon and claims the benefit of priority from Japanese Patent Application No. 2023-127976, filed on Aug. 4, 2023, the entire contents of which are incorporated herein by reference.

### TECHNICAL FIELD

The present disclosure relates to a semiconductor device.

### BACKGROUND

In the related art, a semiconductor device, which includes a semiconductor chip having a main surface, an output region in which output elements are arranged, and a temperature sensing diode structure arranged in the output region, is disclosed.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment of the present disclosure.

FIG. 2 is a cross-sectional view taken along line II-II shown in FIG. 1.

FIG. 3 is a plan view showing an example of a layout within a semiconductor chip shown in FIG. 1.

FIG. 4 is a schematic circuit diagram showing an electrical configuration of the semiconductor device.

FIG. 5 is a schematic circuit diagram showing a configuration of an output transistor shown in FIG. 3.

FIG. 6 is a plan view showing an output region and an inner element region shown in FIG. 3.

FIG. 7 is an enlarged view of region VII shown in FIG. 6.

FIG. 8 is a further enlarged view of the region VII.

FIG. 9 is a cross-sectional view taken along line IX-IX shown in FIG. 7.

FIG. 10 is a cross-sectional view taken along line X-X shown in FIG. 7.

FIG. 11 is a cross-sectional view taken along line XI-XI shown in FIG. 7.

FIG. 12 is a cross-sectional view taken along line XII-XII shown in FIG. 7.

FIG. 13 is a cross-sectional view taken along line XIII-XIII shown in FIG. 7.

FIG. 14 is a plan view showing the inner element region, and is an enlarged view of region XIV shown in FIG. 6.

FIG. 15 is a cross-sectional view taken along line XV-XV shown in FIG. 14.

FIG. 16 is a cross-sectional view taken along line XVI-XVI shown in FIG. 14.

FIG. 17 is a cross-sectional view taken along line XVII-XVII shown in FIG. 14.

FIG. 18 is a cross-sectional view taken along line XVIII-XVIII shown in FIG. 14.

FIG. 19A is a cross-sectional view taken along line XIXA-XIXA shown in FIG. 14.

FIG. 19B is a cross-sectional view taken along line XIXB-XIXB shown in FIG. 6.

FIG. 20 is a plan view showing an example of a layout in a semiconductor chip shown in a reference embodiment.

FIG. 21 is a plan view showing an output region and an inner element region of a semiconductor device according to a second embodiment of the present disclosure, and is a view corresponding to FIG. 6.

FIG. 22 is a plan view showing the inner element region, and is an enlarged view of region XXII shown in FIG. 21.

FIG. 23 is a cross-sectional view taken along line XXIII-XXIII shown in FIG. 22.

FIG. 24 is a cross-sectional view taken along line XXIV-XXIV shown in FIG. 22.

FIG. 25 is a cross-sectional view taken along the line XXV-XXV shown in FIG. 22.

FIG. 26A is a plan view showing an output region and an inner element region of a semiconductor device according to a third embodiment of the present disclosure, and is a view corresponding to FIG. 6.

FIG. 26B is a cross-sectional view taken along line XXVIB-XXVIB shown in FIG. 26A.

FIG. 27 is a plan view showing a first modification of a connection wiring according to the second embodiment, and is a view corresponding to FIG. 25.

FIG. 28 is a cross-sectional view showing a second modification of a planar structure of the semiconductor device according to the first embodiment, and is a view corresponding to FIG. 14.

### DETAILED DESCRIPTION

Hereinafter, embodiments will be described in detail with reference to the accompanying drawings. The accompanying drawings are schematic diagrams and are not strictly illustrated. Scales and the like in the drawings do not necessarily match. In addition, corresponding structures in the accompanying drawings are designated by like reference numerals, and overlapping descriptions thereof will be omitted or simplified.

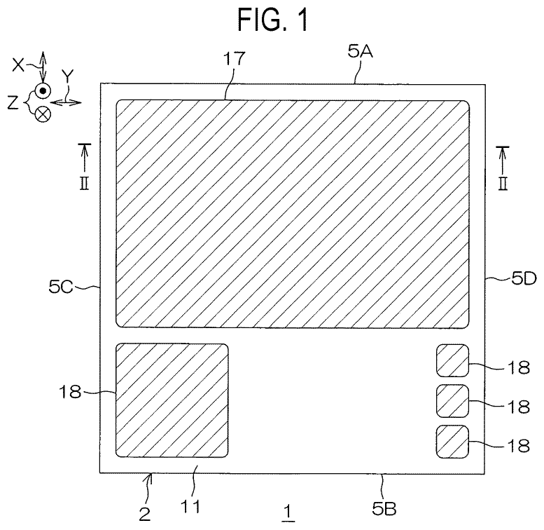

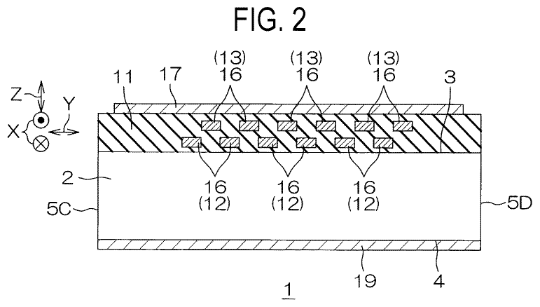

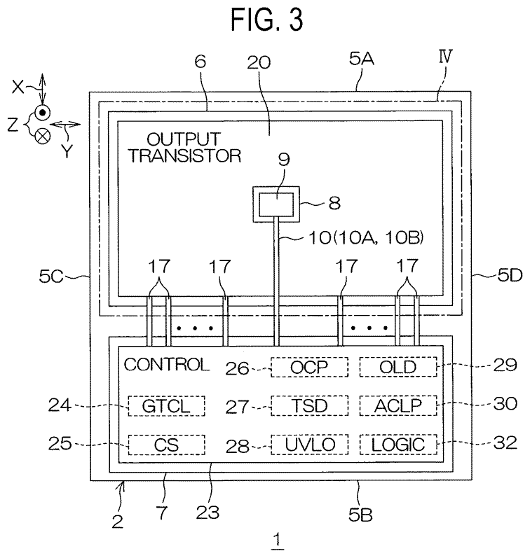

FIG. 1 is a schematic plan view of a semiconductor device 1 according to a first embodiment of the present disclosure. FIG. 2 is a cross-sectional view taken along line II-II shown in FIG. 1. FIG. 3 is a plan view showing an example of a layout in a semiconductor chip 2 shown in FIG. 1.

Referring to FIGS. 1 to 3, the semiconductor device 1 includes the semiconductor chip 2 formed in a rectangular parallelepiped shape. In this embodiment, the semiconductor chip 2 is a Si chip containing a Si single crystal. The semiconductor chip 2 may be constituted by a wide bandgap semiconductor chip containing a single crystal of a wide bandgap semiconductor. The wide bandgap semiconductor is a semiconductor that has a bandgap larger than that of Si. GaN (gallium nitride), SiC (silicon carbide), C (diamond), and the like are exemplified as the wide bandgap semiconductor. For example, the semiconductor chip 2 may be a SiC chip containing a SiC single crystal.

Referring to FIG. 2, the semiconductor chip 2 has a first main surface (main surface) 3 on one side, a second main surface 4 on the other side, and first to fourth side surfaces 5A to 5D that connect the first main surface 3 and the second main surface 4. The first main surface 3 and the second main surface 4 are formed into a quadrangular shape in a plan view when viewed from a normal direction Z thereof (hereinafter simply referred to as “plan view”). The normal direction Z is also a thickness direction of the semiconductor chip 2.

The first main surface 3 is a circuit surface on which various circuit structures constituting an electronic circuit are formed. The second main surface 4 is a non-circuit surface having no circuit structure. The first side surface 5A and the second side surface 5B extend in a second direction Y intersecting (specifically, perpendicularly crossing) a first direction X extending along the first main surface 3, and face (oppose) each other in the first direction X. The third side surface 5C and the fourth side surface 5D extend in the first direction X, and face (oppose) each other in the second direction Y.

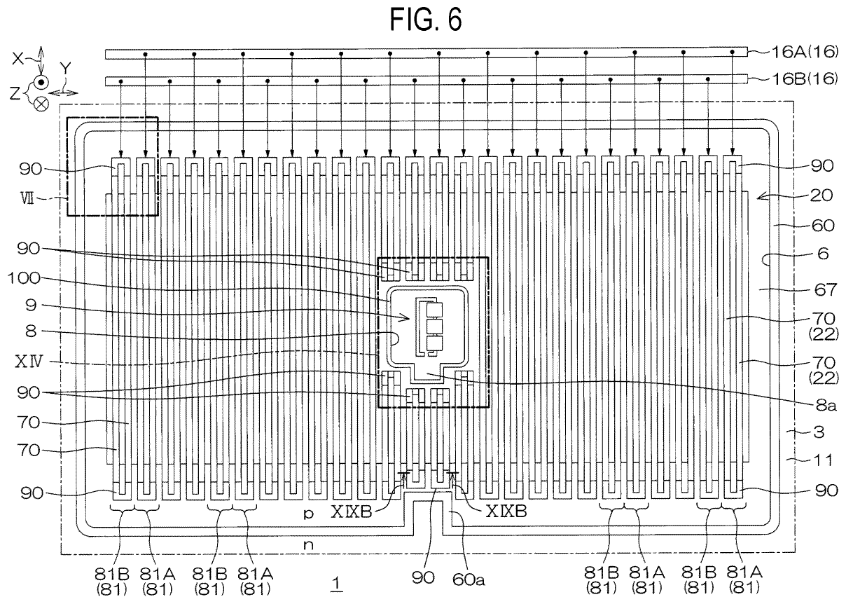

Referring to FIG. 3, the semiconductor device 1 includes an output region 6 provided on the first main surface 3. The output region 6 is a region including an electronic circuit (circuit device) configured to generate an output signal to be outputted to the outside. An output transistor 20 (see FIG. 6) is formed in substantially the entire output region 6 except for inner and outer peripheral portions thereof. In the present embodiment, the output region 6 is defined in a region of the first main surface 3 on the side of the first side surface 5A. The output region 6 has four sides parallel to peripheral edges of the first main surface 3 in a plan view. The output region 6 is an annular (endless) region in a plan view. In the present embodiment, the output region 6 is a substantially quadrangular and annular region.

A position, a size, a planar shape, etc. of the output region 6 are arbitrary and are not limited to a specific layout. The output region 6 may have a planar area of 25% or more and 80% or less of a planar area of the first main surface 3. The planar area of the output region 6 may be 30% or more of the planar area of the first main surface 3. The planar area of the output region 6 may be 40% or more of the planar area of the first main surface 3. The planar area of the output region 6 may be 50% or more of the planar area of the first main surface 3. The planar area of the output region 6 may be 75% or less of the planar area of the first main surface 3.

Referring to FIG. 3, the semiconductor device 1 includes a control region 7 provided in a region different from the output region 6 on the first main surface 3. The control region 7 is an example of an outer region existing outside the output region 6. The control region 7 is a region including a plurality of types of electronic circuits (circuit devices) configured to generate control signals for controlling the output region 6. In the present embodiment, the control region 7 is defined in a region on the side of the second side surface 5B with respect to the output region 6 so as to face the output region 6 in the first direction X. In the present embodiment, the control region 7 is defined in a substantially quadrangular shape having four sides parallel to the peripheral edges of the first main surface 3 in a plan view.

A position, a size, a planar shape, etc. of the control region 7 are arbitrary and are not limited to a specific layout. A planar area of the control region 7 may be approximately equal to the planar area of the output region 6. The planar area of the control region 7 may be larger than the planar area of the output region 6. The planar area of the control region 7 may be smaller than the planar area of the output region 6. A ratio of the planar area of the control region 7 to the planar area of the output region 6 may be 0.1 or more and 4 or less.

Referring to FIG. 3, the semiconductor device 1 includes an inner element region 8 surrounded by the output region 6 on the first main surface 3. The inner element region 8 is arranged at the center of the output region 6. The inner element region 8 is a region insulated and isolated from the output region 6. In the inner element region 8, no unit transistor 22 (see FIG. 6) is formed.

The inner element region 8 is adjacent to the output region 6 in four directions in a plan view. In the present embodiment, the inner element region 8 has a planar area smaller than the planar area of the output region 6. A ratio of the planar area of the inner element region 8 to the planar area of the output region 6 may be 0.001 or more and 0.5 or less. The ratio of the planar area of the inner element region 8 to the planar area of the output region 6 may be 0.01 or more and 0.1 or less.

In the present embodiment, the inner element region 8 is a region for arranging a temperature sensor element 9 as an example of a first element. The inner element region 8 is formed at a position corresponding to the center of the output region 6. Therefore, the temperature sensor element 9 arranged in the inner element region 8 is arranged at a position corresponding to the center of the output region 6. The temperature sensor element 9 is arranged adjacent to the output region 6. The temperature sensor element 9 detects a temperature of the output region 6.

Referring to FIG. 3, the output region 6 surrounds the entire circumference of the inner element region 8. The output region 6 is a quadrangular and annular (endless) region. In other words, the output region 6 surrounds the inner element region 8 such that the inner element region 8 is isolated from the control region 7.

Referring to FIG. 2, the semiconductor device 1 includes an interlayer insulating layer 11 that covers the first main surface 3. The interlayer insulating layer 11 collectively covers the output region 6, the control region 7, and the inner element region 8. In the present embodiment, the interlayer insulating layer 11 has a laminated wiring structure in which a plurality of insulating layers and a plurality of wiring layers are alternately laminated. Each insulating layer includes at least one selected from the group of a SiO₂ film and a SiN film.

The interlayer insulating layer 11 includes a first wiring layer 12 arranged anywhere above the first main surface 3 via an insulating layer, and a second wiring layer 13 arranged anywhere above the first wiring layer 12 via an insulating layer. Each of the first wiring layer 12 and the second wiring layer 13 includes a plurality of output wirings. The plurality of wirings included in the first wiring layer 12 all have the same height from the first main surface 3. The plurality of wirings included in the second wiring layer 13 all have the same height from the first main surface 3. The heights of the first wiring layer 12 and the second wiring layer 13 from the first main surface 3 are different from each other.

The plurality of wirings included in the first wiring layer 12 and the second wiring layer 13 include gate wirings 16.

The semiconductor device 1 includes n gate wirings 16. The n gate wirings 16 are electrically connected to n main gates of an output transistor 20 and a control circuit 23, which will be described later, respectively. Specifically, the n gate wirings 16 are electrically connected to the n main gates (n system gates) of the output transistor 20 in a one-to-one correspondence while being electrically independent from each other. Thus, the n gate wirings 16 individually transmit the n gate signals generated by the control circuit 23 to the n main gates of the output transistor 20. In other words, the n gate wirings 16 are electrically connected to unit gates of one or more unit transistors 22 to be systemized as individual control objects from a group a plurality of unit transistors 22, respectively. The n gate wirings 16 may include one or more gate wirings 16 electrically connected to one unit transistor 22 to be systemized as an individual control object. Further, the n gate wirings 16 may include one or more gate wirings 16 that connect in parallel a plurality of unit transistors 22 to be systemized as individual control objects.

Referring to FIG. 3, a connection wiring 10 is connected to the temperature sensor element 9. The connection wiring 10 is one or more wirings. The connection wiring 10 extends across the output region 6 from the inner element region 8 to the control region 7 located outside the output region 6. The connection wiring 10 connects the temperature sensor element 9 and the control circuit 23 of the control region 7. A first temperature detection signal from the temperature sensor element 9 is applied to an overheat protection circuit 27 of the control circuit 23 via the connection wiring 10. As described later, the connection wiring 10 is included in the second wiring layer 13.

Referring to FIGS. 1 and 2, the semiconductor device 1 includes a plurality of terminals 17 to 19. In FIG. 1, the terminals 17 to 19 are indicated by hatching. The number, an arrangement, and a planar shape of the terminals 17 to 19 may be adjusted to any form according to specifications of the output transistor 20 and the specifications of the control circuit 23, and are not limited to the forms shown in FIGS. 1 and 2. In the present embodiment, the terminals 17 to 19 include a source terminal 17, a plurality of control terminals 18, and a drain terminal 19.

In the present embodiment, the source terminal 17 is provided as an output terminal electrically connected to a load, and is arranged over a portion of the interlayer insulating layer 11 that covers the output region 6. The source terminal 17 may cover the entire output region 6 in a plan view. The source terminal 17 may include at least one selected from the group of a pure Al layer, a Cu layer, an AlCu alloy layer, an AlSiCu alloy layer, and an AlSi alloy layer.

The plurality of control terminals 18 are terminals electrically connected to various electronic circuits within the control region 7, and are arranged over a portion of the interlayer insulating layer 11 that covers the control region 7. The plurality of control terminals 18 have a planar area smaller than the planar area of the source terminal 17, and are arranged at intervals along the peripheral edge of the control region 7 (the peripheral edge of the first main surface 3).

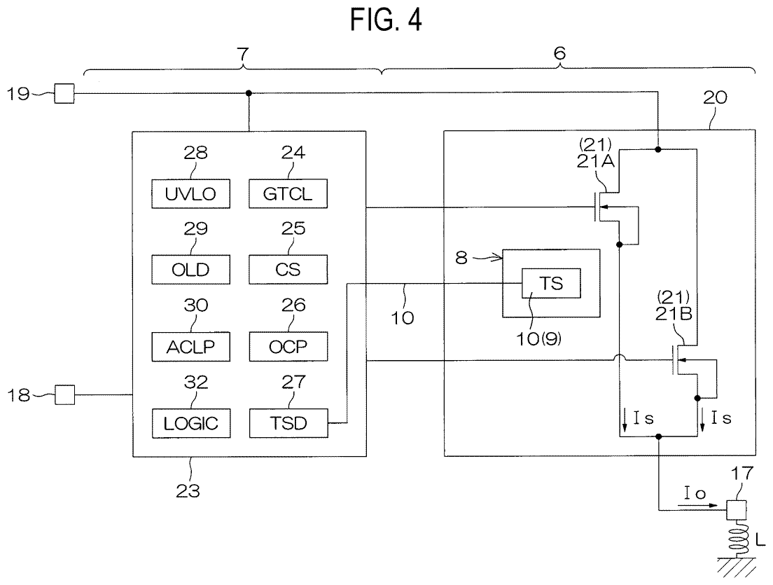

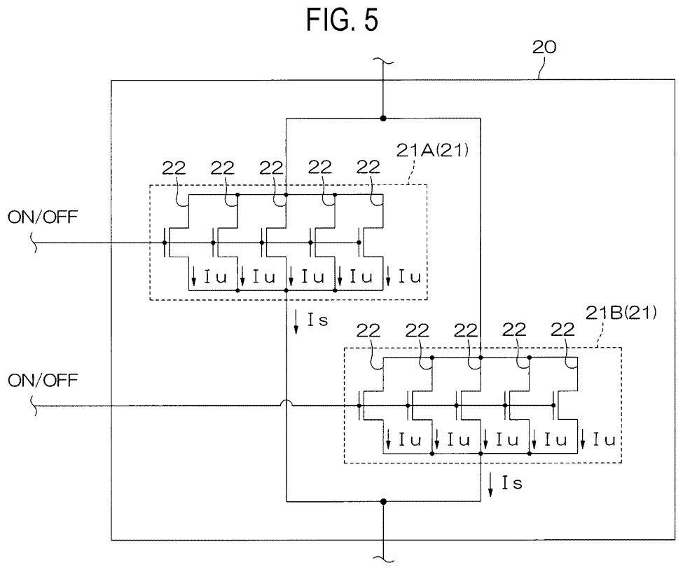

FIG. 4 is a schematic circuit diagram showing an electrical configuration of the semiconductor device 1 shown in FIG. 1. FIG. 5 is a schematic circuit diagram showing a configuration of the output transistor 20. In FIG. 4, in order to show an example of the operation of the semiconductor device 1, there is shown an example in which an inductive load L as an example of a load is electrically connected to the source terminal 17. The inductive load L is not a component of the semiconductor device 1. Therefore, the configuration including the semiconductor device 1 and the inductive load L may be referred to as an “inductive load drive device” or “inductive load control device.” Examples of the inductive load L include relays, solenoids, lamps, motors, and the like. The inductive load L may be a vehicle-mounted inductive load. That is, the semiconductor device 1 may be a vehicle-mounted semiconductor device.

Referring to FIGS. 3 and 4, the semiconductor device 1 includes an output transistor 20 formed in the output region 6. In the present embodiment, the output transistor 20 is constituted by a split-gate transistor including one main drain, one main source, and a plurality of main gates. The main drain is electrically connected to the drain terminal 19 (see FIG. 2). The main source is electrically connected to the source terminal 17 (see FIG. 2).

Referring to FIG. 4, the plurality of main gates of the output transistor 20 are configured such that a plurality of electrically independent gate signals (gate potentials) are individually inputted to the main gates. The output transistor 20 generates a single output current Io (output signal) in response to multiple gate signals. In other words, the output transistor 20 is constituted by a multi-input single-output switching device. The output current Io is a drain-source current flowing between the main drain and the main source. The output current Io is outputted to the outside of the semiconductor chip 2 (the inductive load L) via the source terminal 17.

Referring to FIG. 4, the output transistor 20 includes a plurality of (two or more) system transistors 21 that are electrically controlled independently. In the present embodiment, the plurality of system transistors 21 include a first system transistor 21A and a second system transistor 21B. The plurality of system transistors 21 are collectively formed in the output region 6. The plurality of system transistors 21 are connected in parallel so that a plurality of gate signals are individually inputted to the system transistors 21, and are configured so that the system transistors 21 in an on state and the system transistors 21 in an off state coexist.

The plurality of system transistors 21 includes system drains, system sources, and system gates, respectively. The plurality of system drains are electrically connected to the main drain (drain terminal 19). The plurality of system sources are electrically connected to the main source (source terminal 17). Each system gate is electrically connected to each main gate. In other words, each system gate constitutes each main gate.

Each of the plurality of system transistors 21 generates a system current Is in response to a corresponding gate signal. Each system current Is is a drain-source current flowing between the system drain and the system source of each system transistor 21. A plurality of system currents Is may have different values or may have substantially equal values. The plurality of system currents Is are added between the main drain and the main source. As a result, a single output current Io is generated from a sum of the plurality of system currents Is.

Referring to FIG. 5, each of the plurality of system transistors 21 includes a single or a plurality of unit transistors 22 that are systemized (grouped) as individual control objects. Specifically, the plurality of system transistors 21 are constituted by a single unit transistor 22 or a parallel circuit including a plurality of unit transistors 22. In the present embodiment, the plurality of unit transistors 22 are constituted by trench gate vertical type transistors, respectively. The plurality of system transistors 21 may be constituted by the same number of unit transistors 22 or may be constituted by different numbers of unit transistors 22.

Referring to FIG. 5, each unit transistor 22 includes a unit drain, a unit source, and a unit gate. The unit drain of each unit transistor 22 is electrically connected to the system drain of the corresponding system transistor 21. The unit source of each unit transistor 22 is electrically connected to the system source of the corresponding system transistor 21. The unit gate of each unit transistor 22 is electrically connected to the system gate of the corresponding system transistor 21.

Referring to FIG. 5, the plurality of unit transistors 22 generate unit currents Iu in response to the corresponding gate signals, respectively. Each unit current Iu is a drain-source current flowing between the unit drain and the unit source of each unit transistor 22. The unit currents Iu may have different values or may have substantially equal values. The unit currents Iu are added between the corresponding system drains and system sources. As a result, a system current Is constituted by a sum of a plurality of unit currents Iu is generated.

As described above, the output transistor 20 is configured such that the first system transistor 21A and the second system transistor 21B are controlled to be turned on and off in a state in which they are electrically independent from each other. That is, the output transistor 20 is configured such that both the first system transistor 21A and the second system transistor 21B are turned on at the same time. Further, the output transistor 20 is configured such that one of the first system transistor 21A and the second system transistor 21B is turned on and the other is turned off.

Referring to FIG. 5, when both the first system transistor 21A and the second system transistor 21B are turned on at the same time, a channel utilization rate of the output transistor 20 increases and an on-resistance of the output transistor 20 decreases. When one of the first system transistor 21A and the second system transistor 21B is turned on while the other is turned off, the channel utilization rate of the output transistor 20 decreases and the on-resistance of the output transistor 20 increases. In other words, the output transistor 20 is constituted by a variable on-resistance switching device.

Referring to FIGS. 3 and 4, the semiconductor device 1 includes a control circuit 23 formed in the control region 7 so that the control circuit 23 is electrically connected to the output transistor 20. The control circuit 23 may also be referred to as a “control IC.” The control circuit 23 includes various functional circuits, and constitutes an intelligent power device (IPD) together with the output transistor 20. The IPD may be referred to as an “intelligent power module (IPM),” “intelligent power switch (IPS),” “smart power driver,” “smart MISFET (smart MOSFET),” or “protected MISFET (protected MOSFET).”

Referring to FIGS. 3 and 4, in the present embodiment, the control circuit 23 includes a gate control circuit 24, a current monitor circuit 25, an overcurrent protection circuit 26, an overheat protection circuit 27, a low voltage malfunction avoidance circuit 28, an open load detection circuit 29, an active clamp circuit 30, and a logic circuit 32. The control circuit 23 does not necessarily need to include all of these functional circuits at the same time, but only needs to include at least one of these functional circuits.

The current monitor circuit 25 may be called a current sense circuit (CS circuit). The overcurrent protection circuit 26 may be called an over current protection circuit (OCP circuit). The overheat protection circuit 27 may be called a thermal shut down circuit (TSD circuit). The low voltage malfunction avoidance circuit 28 may be called an under voltage lock out circuit (UVLO circuit). The open load detection circuit 29 may be called an open load detection circuit (OLD circuit).

The gate control circuit 24 is configured to generate a gate signal that controls the on/off operation of the output transistor 20. Specifically, the gate control circuit 24 generates a plurality of gate signals that individually control the on/off operations of the plurality of system transistors 21. In other words, in the present embodiment, the gate control circuit 24 generates a first gate signal that individually controls the on/off operation of the first system transistor 21A, and a second gate signal that individually controls the on/off operation of the second system transistor 21B electrically independently from the first system transistor 21A.

The current monitor circuit 25 generates a monitor current for monitoring the output current Io (see FIG. 4) of the output transistor 20, and outputs the monitor current to other circuits. For example, the monitor circuit may include a transistor having the same configuration as the output transistor 20, and may be configured to generate a monitor current linked to the output current Io by being on/off controlled at the same time as the output transistor 20. Of course, the current monitor circuit 25 may be configured to generate a monitor current linked to one or more system currents Is.

The overcurrent protection circuit 26 generates an electric signal to control the gate control circuit 24 based on the monitor current from the current monitor circuit 25, and controls the on/off operation of the output transistor 20 in cooperation with the gate control circuit 24. For example, the overcurrent protection circuit 26 may be configured to determine that the output transistor 20 is in an overcurrent state when the monitor current becomes a predetermined threshold value or greater, and control a part or all of the output transistor 20 (the plurality of system transistors 21) to be turned off in cooperation with the gate control circuit 24. Further, the overcurrent protection circuit 26 may be configured to shift the output transistor 20 to a normal operation in cooperation with the gate control circuit 24 when the monitor current becomes less than a predetermined threshold value.

As described above, the overheat protection circuit 27 is given the first temperature detection signal from the temperature sensor element 9 configured to detect the temperature of the output region 6. The overheat protection circuit 27 also includes a temperature sensing device (e.g., a temperature sensing diode) configured to detect the temperature of the control region 7. The overheat protection circuit 27 generates an electric signal for controlling the gate control circuit 24 based on the first temperature detection signal from the temperature sensor element 9 and a second temperature detection signal from the temperature sensing device, and controls the on/off operation of the output transistor 20 in cooperation with the gate control circuit 24.

For example, the overheat protection circuit 27 may be configured to determine that the output region 6 is in an overheated state when a difference value between the first temperature detection signal and the second temperature detection signal becomes a predetermined threshold value or greater, and control a part or all of the output transistor 20 (the plurality of system transistors 21) to be turned off in cooperation with the gate control circuit 24. Further, the overheat protection circuit 27 may be configured to shift the output transistor 20 to a normal operation in cooperation with the gate control circuit 24 when the difference value becomes less than a predetermined threshold value.

The low voltage malfunction avoidance circuit 28 is configured to prevent various functional circuits within the control circuit 23 from malfunctioning when a starting voltage for starting the control circuit 23 is less than a predetermined value. For example, the low voltage malfunction avoidance circuit 28 may be configured to start the control circuit 23 when the starting voltage becomes equal to or higher than the predetermined threshold voltage, and stop the control circuit 23 when the starting voltage becomes less than the threshold voltage. The threshold voltage may have hysteresis characteristics.

The open load detection circuit 29 determines an electrical connection state of the inductive load L. For example, the open load detection circuit 29 may be configured to monitor the voltage between the terminals of the output transistor 20, and determine that the inductive load L is in an open state when the voltage between the terminals becomes equal to or higher than a predetermined threshold value. For example, the open load detection circuit 29 may be configured to determine that the inductive load L is in the open state when the monitor current becomes equal to or less than a predetermined threshold value.

The active clamp circuit 30 is electrically connected to the main drain and at least one main gate of the output transistor 20 (e.g., the system gate of the first system transistor 21A). The active clamp circuit 30 includes a Zener diode and a pn junction diode connected in reverse bias series to the Zener diode. The pn junction diode is a backflow prevention diode configured to prevent backflow from the output transistor 20.

The active clamp circuit 30 is configured to control a part or all of the output transistor 20 to be turned on in cooperation with the gate control circuit 24 when a counter electromotive voltage caused by the inductive load L is applied to the output transistor 20. Specifically, the output transistor 20 is controlled in multiple types of operation modes including a normal operation, a first off operation, an active clamp operation, and a second off operation.

In the normal operation, both the first system transistor 21A and the second system transistor 21B are controlled to be turned on at the same time. This increases the channel utilization rate of the output transistor 20 and reduces the on-resistance. In the first off operation, both the first system transistor 21A and the second system transistor 21B are controlled from the on state to an off state at the same time. As a result, the counter electromotive voltage caused by the inductive load L is applied to both the first system transistor 21A and the second system transistor 21B.

The active clamp operation is an operation in which the output transistor 20 absorbs (consumes) the energy stored in the inductive load L, and is executed when the counter electromotive voltage caused by the inductive load L becomes equal to or higher than a predetermined threshold voltage. In the active clamp operation, the first system transistor 21A is controlled from an off state to an on state, and at the same time, the second system transistor 21B is controlled to (maintained in) an off state.

The channel utilization rate of the output transistor 20 during the active clamp operation is less than the channel utilization rate of the output transistor 20 during the normal operation. The on-resistance of the output transistor 20 during the active clamp operation is larger than the on-resistance of the output transistor 20 during the normal operation. This suppresses a rapid temperature rise in the output transistor 20 during the active clamp operation, and improves active clamp durability.

The second off operation is performed when the counter electromotive voltage becomes less than the predetermined threshold voltage. In the second off operation, the first system transistor 21A is controlled from the on state to the off state, and at the same time, the second system transistor 21B is controlled to (maintained in) the off state. In this way, the counter electromotive voltage (energy) of the inductive load L is absorbed by a part of the output transistor 20 (here, the first system transistor 21A). Of course, during the active clamp operation, the first system transistor 21A may be controlled to (maintained in) the off state, and at the same time, the second system transistor 21B may be controlled to the on state.

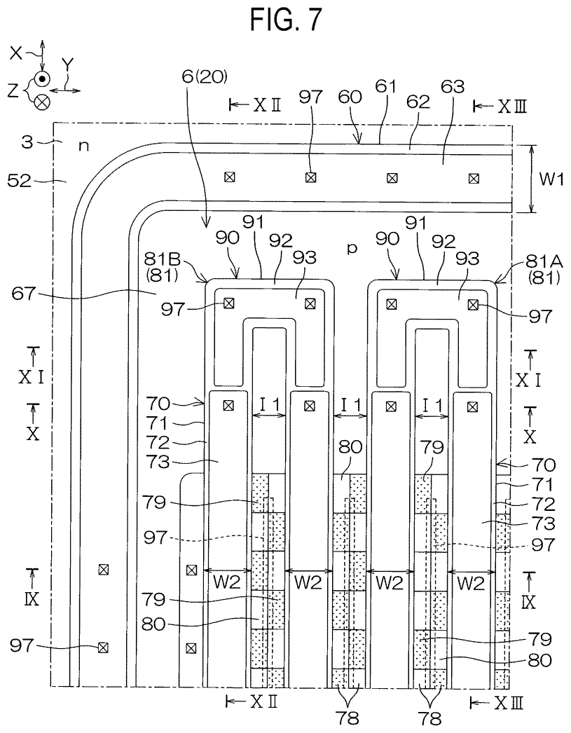

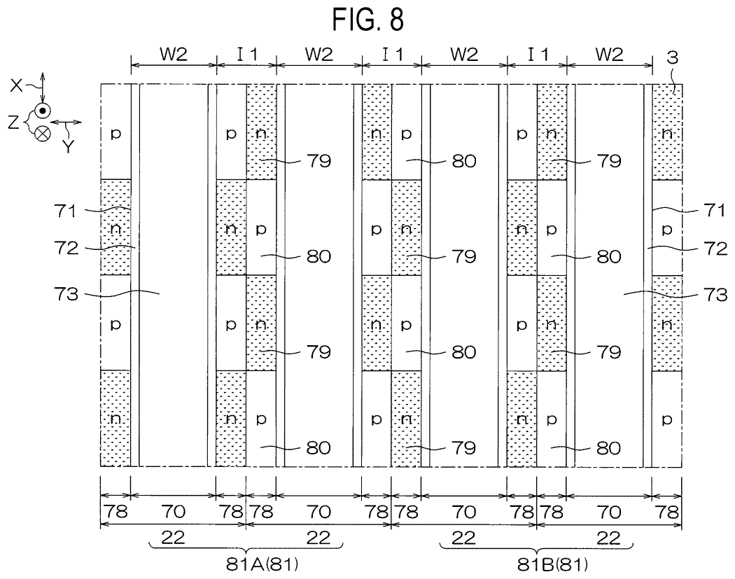

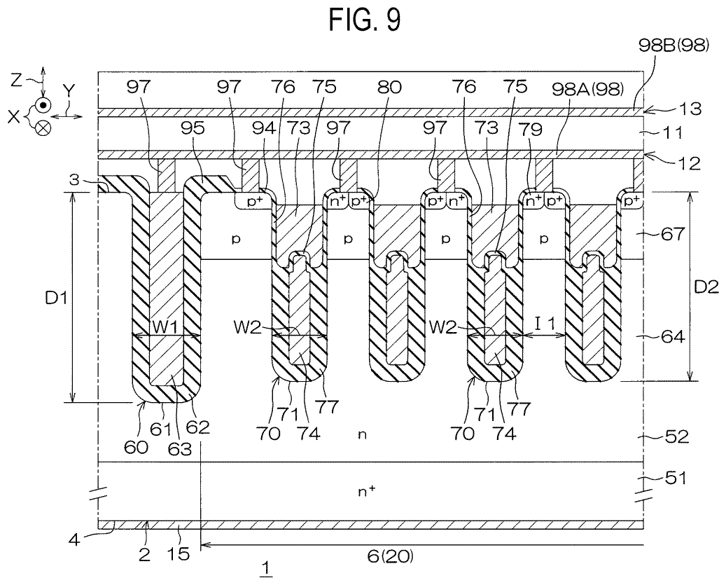

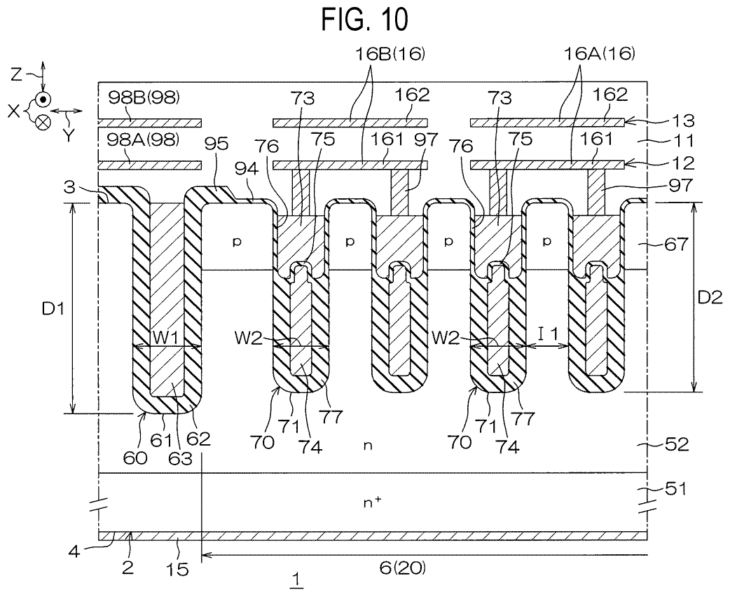

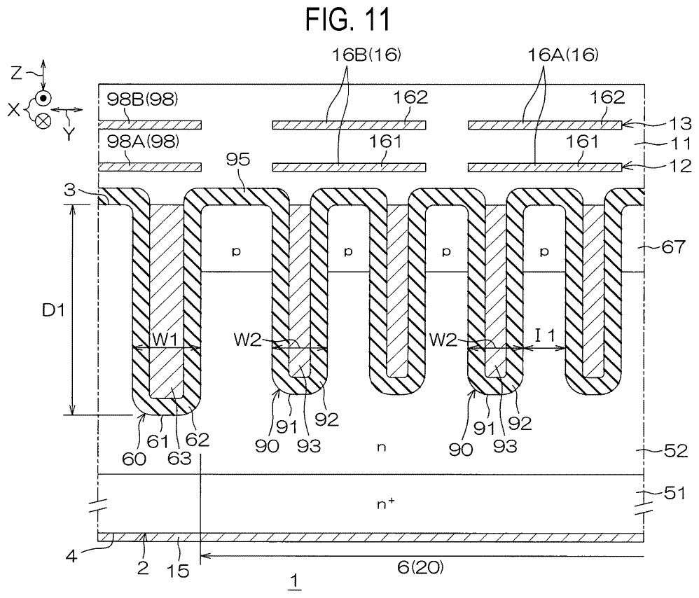

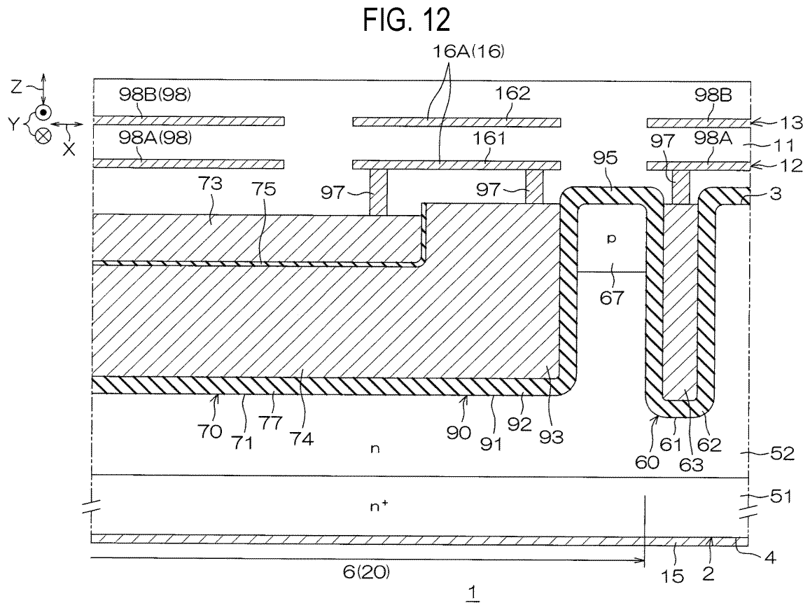

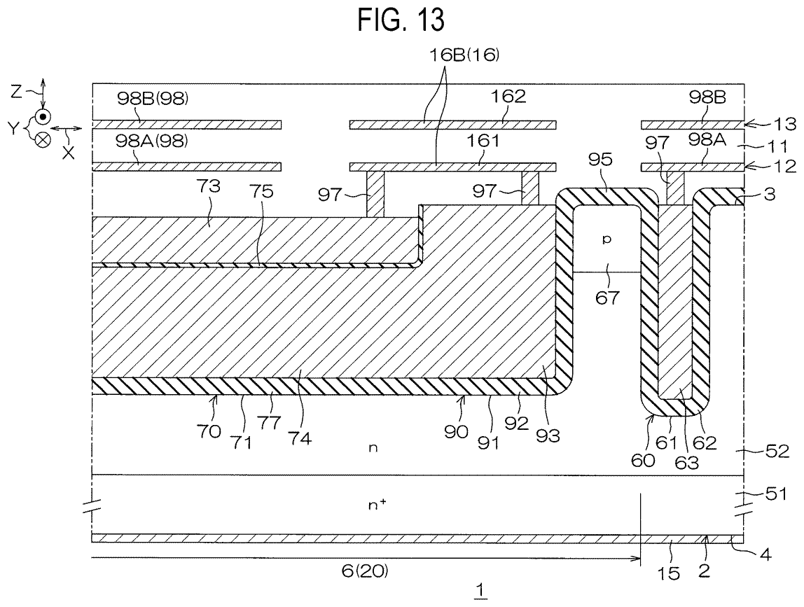

A configuration of the output region 6 will be described below with reference to FIGS. 6 to 13. FIG. 6 is a plan view showing the output region 6 and the inner element region 8. FIG. 7 is an enlarged view of region VII shown in FIG. 6. FIG. 8 is a further enlarged view of region VII. FIG. 9 is a cross-sectional view taken along line IX-IX shown in FIG. 7. FIG. 10 is a cross-sectional view taken along line X-X shown in FIG. 7. FIG. 11 is a cross-sectional view taken along line XI-XI shown in FIG. 7. FIG. 12 is a cross-sectional view taken along line XII-XII shown in FIG. 7. FIG. 13 is a cross-sectional view taken along line XIII-XIII shown in FIG. 7.

The semiconductor device 1 includes an n-type (first conductivity type) first semiconductor region 51 formed in a surface layer portion of the second main surface 4 of the semiconductor chip 2. The first semiconductor region 51 forms the main drain of the output transistor 20 and the system drain of the system transistor 21. The first semiconductor region 51 may be referred to as a “drain region.” The first semiconductor region 51 is formed over the entire surface layer of the second main surface 4, and is exposed from the second main surface 4 and the first to fourth side surfaces 5A to 5D (see FIG. 1, etc.).

The n-type impurity concentration of the first semiconductor region 51 may be 1×10¹⁸ cm⁻³ or more and 1×10²¹ cm⁻³ or less. A thickness of the first semiconductor region 51 may be 10 μm or more and 450 μm or less. A thickness of the first semiconductor region 51 is preferably 50 μm or more and 150 μm or less. In the present embodiment, the first semiconductor region 51 is formed of an n-type semiconductor substrate (Si substrate).

The semiconductor device 1 includes an n-type second semiconductor region 52 formed in the surface layer portion of the first main surface 3 of the semiconductor chip 2. The second semiconductor region 52 forms the main drain of the output transistor 20 and the system drain of the system transistor 21 together with the first semiconductor region 51. The second semiconductor region 52 may be referred to as a “drift region.” The second semiconductor region 52 is formed over the entire surface layer of the first main surface 3 so as to be electrically connected to the first semiconductor region 51, and is exposed from the first main surface 3 and the first to fourth side surfaces 5A to 5D (see FIG. 1, etc.).

The second semiconductor region 52 has an n-type impurity concentration lower than the n-type impurity concentration of the first semiconductor region 51. The n-type impurity concentration of the second semiconductor region 52 may be 1×10¹⁵ cm⁻³ or more and 1×10¹⁸ cm⁻³ or less. The second semiconductor region 52 has a thickness less than the thickness of the first semiconductor region 51. The thickness of the second semiconductor region 52 may be 1 μm or more and 25 μm or less. The thickness of the second semiconductor region 52 is preferably 5 μm or more and 15 μm or less. In the present embodiment, the second semiconductor region 52 is formed of an n-type epitaxial layer (Si epitaxial layer).

The semiconductor device 1 includes a first trench isolation structure 60 as an example of a region isolation structure that defines the outer edge of the output region 6 on the first main surface 3. The first trench isolation structure 60 may be referred to as a “deep trench isolation (DTI) structure.” The first trench isolation structure 60 may also be referred to as an “outer isolation structure.”

Referring to FIG. 6, the first trench isolation structure 60 is formed in an annular shape surrounding the outer periphery of the output region 6 in a plan view. In the present embodiment, the first trench isolation structure 60 is formed into a substantially quadrangular and annular shape having four sides parallel to the peripheral edge of the first main surface 3 in a plan view. Strictly speaking, the first trench isolation structure 60 has a protrusion 60a formed in a region facing the inner element region 8 across the output region 6 (in a region facing a below-described protrusion 8a in the first direction X) and configured to protrude toward the inner element region 8 in the first direction X. A planar shape of the first trench isolation structure 60 is arbitrary, and may be formed in a polygonal and annular shape.

Referring to FIGS. 9 to 13, the first trench isolation structure 60 includes a first isolation trench 61, a first isolation insulating film 62, and a first isolation electrode 63. That is, the first trench isolation structure 60 has a single electrode structure including a single electrode (first isolation electrode 63) buried in the first isolation trench 61 with an insulator (first isolation insulating film 62) interposed therebetween.

The first isolation trench 61 is dug down from the first main surface 3 toward the second main surface 4. The first isolation trench 61 is formed at an interval from a bottom of the second semiconductor region 52 toward the first main surface 3. The first isolation insulating film 62 covers a wall surface of the first isolation trench 61. The first isolation insulating film 62 may include a silicon oxide film. The first isolation insulating film 62 may include a silicon oxide film made of the oxide of the semiconductor chip 2, or may include a silicon oxide film formed by a CVD method. The first isolation electrode 63 is buried in the first isolation trench 61 with the first isolation insulating film 62 interposed therebetween. The first isolation electrode 63 may contain conductive polysilicon.

Referring to FIG. 7 and FIGS. 9 to 11, the first trench isolation structure 60 has a first isolation width W1 and a first isolation depth D1. The first isolation width W1 is a width in a direction perpendicular to a direction in which the first trench isolation structure 60 extends in a plan view. The first isolation width W1 may be 0.5 μm or more and 2.5 μm or less. The first isolation width W1 is preferably 1.2 μm or more and 2 μm or less. The first isolation depth D1 may be 1 μm or more and 10 μm or less. The first isolation depth D1 is preferably 2 μm or more and 6 μm or less.

An aspect ratio D1/W1 of the first trench isolation structure 60 may be greater than 1 and less than or equal to 5. The aspect ratio D1/W1 is a ratio of the first isolation depth D1 to the first isolation width W1. The aspect ratio D1/W1 is preferably 2 or more. A bottom wall of the first trench isolation structure 60 is preferably spaced apart from the bottom of the second semiconductor region 52 by 1 μm or more and 5 μm or less.

Referring to FIGS. 6 and 7, the first trench isolation structure 60 has corners, each of which connects a portion extending in the first direction X and a portion extending in the second direction Y in an arc shape (curved shape). In the present embodiment, the four corners of the first trench isolation structure 60 are formed in an arc shape. That is, the output region 6 is defined in a rectangular shape having four corners each extending in an arc shape. It is preferable that the corners of the first trench isolation structure 60 have a constant first isolation width W1 along an arc direction.

Referring to FIGS. 9 to 13, the first isolation trench 61 includes sidewalls and a bottom wall. An angle between a sidewall of the first isolation trench 61 and the first main surface 3 within the semiconductor chip 2 may be 90 degrees or more and 92 degrees or less. The first isolation trench 61 may be formed in a tapered shape in which an opening width grows smaller from the opening toward the bottom wall. Bottom wall corners of the first isolation trench 61 are preferably formed into a curved shape. The entire bottom wall of the first isolation trench 61 may be formed in a curved shape toward the second main surface 4.

The first isolation insulating film 62 is formed on the wall surface of the first isolation trench 61. Specifically, the first isolation insulating film 62 is formed in a film shape over the entire wall surface of the first isolation trench 61 to define a recess space within the first isolation trench 61. Preferably, the first isolation insulating film 62 includes a silicon oxide film. It is more preferable that the first isolation insulating film 62 includes a silicon oxide film made of the oxide of the semiconductor chip 2.

The first isolation electrode 63 is buried as an integrated member in the first isolation trench 61 with the first isolation insulating film 62 interposed therebetween. In the present embodiment, the first isolation electrode 63 contains conductive polysilicon. A source potential is applied to the first isolation electrode 63. The first isolation electrode 63 has an electrode surface (isolation electrode surface) exposed from the first isolation trench 61. The electrode surface of the first isolation electrode 63 may be recessed in a curved shape toward the bottom wall of the first isolation trench 61. The electrode surface of the first isolation electrode 63 is preferably spaced apart from the first main surface 3 to the bottom wall of the first isolation trench 61 in the depth direction of the first isolation trench 61.

Referring to FIGS. 7 to 13, the semiconductor device 1 includes a p-type (second conductivity type) first body region 67 formed in the surface layer portion of the first main surface 3 in the output region 6. The p-type impurity concentration of the first body region 67 may be 1×10¹⁶ cm⁻³ or more and 1×10¹⁸ cm⁻³ or less. The first body region 67 is formed over the entire surface layer portion of the first main surface 3 in the output region 6 and is in contact with the sidewall of the first trench isolation structure 60. The first body region 67 is formed in a region on the side of the first main surface 3 with respect to the bottom wall of the first trench isolation structure 60. The first body region 67 is preferably formed in a region on the side of the first main surface 3 with respect to the intermediate portion of the first trench isolation structure 60.

Referring to FIG. 6, as described above, the semiconductor device 1 includes the output transistor 20 formed on the first main surface 3 in the output region 6. The output transistor 20 is arranged in a ring shape surrounding the inner element region 8. The output transistor 20 includes a plurality of unit transistors 22 (see FIG. 8) that are collectively formed on the first main surface 3 in the output region 6. The number of unit transistors 22 is arbitrary. The number of unit transistors 22 is preferably an even number. The unit transistors 22 are arranged along a line in the second direction Y in a plan view, and are respectively formed in a band shape extending in the first direction X. The unit transistors 22 are formed in a stripe shape extending in the first direction X in a plan view.

Referring to FIG. 8, each unit transistor 22 includes one trench gate structure (trench electrode structure) 70 and a channel cell 78 controlled by the trench gate structure 70. Each trench gate structure 70 constitutes a unit gate of each unit transistor 22. The channel cell 78 is a region where opening and closing of a current path is controlled by the trench gate structure 70. In the present embodiment, each unit transistor 22 includes a pair of channel cells 78 formed on both sides of one trench gate structure 70.

Referring to FIGS. 7 and 8, the trench gate structures 70 are arranged at intervals in the second direction Y in a plan view, and are respectively formed in a band shape extending in the first direction X. That is, the trench gate structures 70 are formed in a stripe shape extending in the first direction X in a plan view.

Referring to FIGS. 7 to 10, the trench gate structures 70 have a trench width W2 and a trench depth D2. The trench width W2 is a width in a direction (second direction Y) orthogonal to a direction in which the trench gate structure 70 extends. The trench width W2 is preferably less than the first isolation width W1 of the first trench isolation structure 60 (W2<W1). The trench width W2 may be 0.5 μm or more and 2 μm or less. The trench width W2 is preferably 0.5 μm or more and 1.5 μm or less. Of course, the trench width W2 may be approximately equal to the first isolation width W1 (W2≈W1).

The trench depth D2 is preferably less than the first isolation depth D1 of the first trench isolation structure 60 (D2<D1). The trench depth D2 may be 1 μm or more and 10 μm or less. The trench depth D2 is preferably 2 μm or more and 6 μm or less. Of course, the trench depth D2 may be approximately equal to the first isolation depth D1 (D2=D1). An aspect ratio D2/W2 of the trench gate structure 70 may be greater than 1 and less than or equal to 5. The aspect ratio D2/W2 is a ratio of the trench depth D2 to the trench width W2. It is more preferable that the aspect ratio D2/W2 is 2 or more. The bottom wall of the trench gate structure 70 is preferably spaced apart from the bottom of the second semiconductor region 52 by 1 μm or more and 5 μm or less.

Referring to FIGS. 7 to 10, the trench gate structures 70 are arranged in the second direction Y at a first interval I1. The first interval I1 is also a mesa width of a mesa portion defined in a region between two trench gate structures 70 adjacent to each other. The first interval I1 is preferably equal to or less than the first isolation width W1 of the first trench isolation structure 60. It is preferable that the first interval I1 is equal to or less than the trench width W2. It is particularly preferable that the first interval I1 is less than the trench width W2. The first interval I1 may be 0.5 μm or more and 2 μm or less.

An internal configuration of one trench gate structure 70 will be described below. Referring to FIGS. 9 to 13, the trench gate structure 70 includes a gate trench 71, an insulating film 72, an upper electrode 73, a lower electrode 74, and an intermediate insulating film 75. In other words, the trench gate structure 70 has a multi-electrode structure including a plurality of electrodes (the upper electrode 73 and the lower electrode 74) buried vertically in the gate trench 71 with insulators (the insulating film 72 and the intermediate insulating film 75) interposed therebetween.

The gate trench 71 is dug down from the first main surface 3 toward the second main surface 4. The gate trench 71 penetrates the first body region 67 and is formed at an interval from the bottom of the second semiconductor region 52 toward the first main surface 3. The gate trench 71 includes sidewalls and a bottom wall. An angle between a sidewall of the gate trench 71 and the first main surface 3 within the semiconductor chip 2 may be 90 degrees or more and 92 degrees or less. The gate trench 71 may be formed in a tapered shape in which an opening width grows smaller from the opening toward the bottom wall. It is preferable that bottom wall corners of the gate trench 71 are formed in a curved shape. The entire bottom wall of the gate trench 71 may be formed in a curved shape toward the second main surface 4. The insulating film 72 covers a wall surface of the gate trench 71. The insulating film 72 includes an upper insulating film 76 and a lower insulating film 77. The upper insulating film 76 covers the wall surface of the gate trench 71 on the side of the opening with respect to the bottom of the first body region 67.

The upper insulating film 76 partially covers the wall surface of the gate trench 71 on the side of the bottom wall with respect to the bottom of the first body region 67. The upper insulating film 76 is thinner than the first isolation insulating film 62. The upper insulating film 76 is formed as a gate insulating film. The upper insulating film 76 may include a silicon oxide film. Preferably, the upper insulating film 76 includes a silicon oxide film made of the oxide of the semiconductor chip 2.

The lower insulating film 77 covers the wall surface of the gate trench 71 on the side of the bottom wall with respect to the bottom of the first body region 67. A lower insulating film 77 is thicker than the upper insulating film 76. The thickness of the lower insulating film 77 may be approximately equal to a thickness of the first isolation insulating film 62. The lower insulating film 77 may include a silicon oxide film. The lower insulating film 77 may include a silicon oxide film made of the oxide of the semiconductor chip 2, or may include a silicon oxide film formed by a CVD method.

The upper electrode 73 is buried in the gate trench 71 on the side of the opening with the insulating film 72 interposed therebetween. Specifically, the upper electrode 73 is buried in the gate trench 71 on the side of the opening with the upper insulating film 76 interposed therebetween, and faces the first body region 67 with the upper insulating film 76 interposed therebetween. The upper electrode 73 may be made of conductive polysilicon.

The lower electrode 74 is buried in the gate trench 71 on the side of the bottom wall with the insulating film 72 interposed therebetween. The lower electrode 74 has an upper end that protrudes from the lower insulating film 77 toward the upper electrode 73 so as to engage with the bottom of the upper electrode 73. The upper end of the lower electrode 74 faces the upper insulating film 76 across the lower end of the upper electrode 73 in the lateral direction along the first main surface 3. The lower electrode 74 may be made of conductive polysilicon.

The intermediate insulating film 75 is interposed between the upper electrode 73 and the lower electrode 74 to electrically insulate the upper electrode 73 and the lower electrode 74 within the gate trench 71. The intermediate insulating film 75 is continuous with the upper insulating film 76 and the lower insulating film 77. The intermediate insulating film 75 is thinner than the lower insulating film 77. The intermediate insulating film 75 may include a silicon oxide film. The intermediate insulating film 75 preferably includes a silicon oxide film made of the oxide of the lower electrode 74.

As mentioned above, each unit transistor 22 includes the channel cell 78 controlled by the trench gate structure 70. In the present embodiment, two channel cells 78 arranged on both sides of one trench gate structure 70 are controlled by the one trench gate structure 70 and are not controlled by other trench gate structures 70.

Referring to FIG. 8, a plurality of channel cells 78 are formed in a region along an inner portion of the trench gate structure 70 at intervals from both ends of the trench gate structure 70 in a longitudinal direction (first direction X) of the trench gate structure 70. The plurality of channel cells 78 expose the first body region 67 from a region of the first main surface 3 sandwiched between both ends of the plurality of trench gate structures 70.

Referring to FIG. 8, each channel cell 78 includes a plurality of n-type source regions 79 and a plurality of p-type contact regions 80. In FIG. 8, the source regions 79 are hatched for clarity. The contact regions 80 may also be referred to as “back gate regions.” The n-type impurity concentration of each source region 79 may be 1×10¹⁸ cm⁻³ or more and 1×10²¹ cm⁻³ or less.

Referring to FIGS. 8 and 9, the source regions 79 are arranged at intervals along each trench gate structure 70. The source regions 79 are formed at intervals from the bottom of the first body region 67 toward the first main surface 3, and face the upper electrode 73 with the insulating film 72 (upper insulating film 76) interposed therebetween. All the source regions 79 included in each unit transistor 22 form a unit source of each unit transistor 22.

Referring to FIGS. 8 and 9, each contact region 80 has a higher p-type impurity concentration than the first body region 67. The p-type impurity concentration of each contact region 80 may be 1×10¹⁸ cm⁻³ or more and 1×10²¹ cm⁻³ or less. The contact regions 80 are arranged alternately with the source regions 79 along each trench gate structure 70. The contact regions 80 are formed at intervals from the bottom of the first body region 67 toward the first main surface 3, and face the upper electrode 73 with the insulating film 72 (upper insulating film 76) interposed therebetween.

Referring to FIG. 8, regarding the two channel cells 78 formed on both sides of one trench gate structure 70, the source regions 79 in one channel cell 78 face the source regions 79 in the other channel cell 78 with the trench gate structure 70 interposed therebetween. Further, the contact regions 80 in one channel cell 78 face the contact regions 80 in the other channel cell 78 with the trench gate structure 70 interposed therebetween.

Of course, the source regions 79 in one channel cell 78 may face the contact regions 80 in the other channel cell 78 with the trench gate structure 70 interposed therebetween. Further, the contact regions 80 in one channel cell 78 may face the source regions 79 in the other channel cell 78 with the trench gate structure 70 interposed therebetween.

Regarding the two channel cells 78 interposed between two trench gate structures 70, the source regions 79 in one channel cell 78 are connected to the contact regions 80 in the other channel cell 78 in the second direction Y. Further, the contact regions 80 in one channel cell 78 are connected to the source regions 79 in the other channel cell 78 in the second direction Y.

Of course, the source regions 79 in one channel cell 78 may be connected to the source regions 79 in the other channel cell 78 in the second direction Y. Further, the contact regions 80 in one channel cell 78 may be connected to the contact regions 80 in the other channel cell 78 in the second direction Y.

Of the two channel cells 78 formed on both sides of the outermost trench gate structure 70, the channel cell 78 located on the inner side faces the second semiconductor region 52 with a portion of the first body region 67 interposed therebetween in the thickness direction. On the other hand, the channel cell 78 located on the outer side does not include the source region 79 but includes only the contact region 80. This suppresses formation of a current path in the region between the first trench isolation structure 60 and the outermost trench gate structure 70.

Referring to FIGS. 7 and 8, the output transistor 20 includes a plurality of unit transistors 22. Each of the plurality of unit transistors 22 includes one trench gate structure 70 and two channel cells 78 formed on both sides of the one trench gate structure 70. Regarding each unit transistor 22, one trench gate structure 70 constitutes a unit gate, the source regions 79 (two channel cells 78) constitute a unit source, and the first semiconductor region 51 constitutes a unit drain.

As described above, the output transistor 20 includes the first system transistor 21A (see FIG. 5) and the second system transistor 21B (see FIG. 5). The first system transistor 21A includes a plurality of unit transistors 22 that are systemized (grouped) as individual control targets from the plurality of unit transistors 22. The second system transistor 21B includes a plurality of unit transistors 22 that are systemized (grouped) as individual control targets from the plurality of unit transistors 22 other than the first system transistor 21A.

Referring to FIGS. 7 and 8, in the present embodiment, the output transistor 20 includes a plurality of block regions 81 provided in the output region 6. The block regions 81 include a plurality of first block regions 81A and a plurality of second block regions 81B. The first block regions 81A are regions in which one or more (in the present embodiment, a plurality of) unit transistors 22 (see FIG. 5) for the first system transistor 21A (see FIG. 5) are arranged respectively. The second block regions 81B are regions in which one or more (a plurality of, in the present embodiment) unit transistors 22 (see FIG. 5) for the second system transistor 21B (see FIG. 5) are arranged.

The first block regions 81A are arranged at intervals in the second direction Y. The number of unit transistors 22 in each first block region 81A is arbitrary. In the present embodiment, two unit transistors 22 are arranged in each first block region 81A. When the number of unit transistors 22 in each first block region 81A increases, an amount of heat generated in each first block region 81A increases. Therefore, the number of unit transistors 22 in each first block region 81A is preferably 2 or more and 5 or less.

The second block regions 81B are arranged alternately with the first block regions 81A along the second direction Y so as to sandwich one first block region 81A. As a result, the heat generation locations attributable to the first block regions 81A can be thinned out by the second block regions 81B, and the heat generation locations attributable to the second block regions 81B can be thinned out by the first block regions 81A.

The number of unit transistors 22 in each second block region 81B is arbitrary. In the present embodiment, two unit transistors 22 are arranged in each second block region 81B. When the number of unit transistors 22 in each second block region 81B increases, an amount of heat generated in each second block region 81B increases.

Therefore, the number of unit transistors 22 in each second block region 81B is preferably 2 or more and 5 or less. Considering the in-plane temperature variations in the output region 6, the number of unit transistors 22 in the second block region 81B is preferably the same as the number of unit transistors 22 in the first block region 81A.

Referring to FIGS. 6 and 7, the semiconductor device 1 includes a pair of trench connection structures 90 configured to connect both ends of a plurality of (two, in the present embodiment) trench gate structures 70 to be systemized (grouped) in each block region 81. That is, the pair of trench connection structures 90 connects both ends of the plurality of trench gate structures 70 to be systemized as the system transistors 21, respectively.

Referring to FIG. 6, the trench connection structure 90 on one side connects the first ends of a plurality of (two, in the present embodiment) corresponding trench gate structures 70 in an arch shape in a plan view. The trench connection structure 90 on the other side connects the second ends of a plurality of (two, in the present embodiment) corresponding trench gate structures 70 in an arch shape in a plan view.

Specifically, the trench connection structure 90 on one side has a first portion extending in the second direction Y, and a plurality of (two, in the present embodiment) second portions extending in the first direction X. The first portion faces the first ends of the plurality of trench gate structures 70 in a plan view. The second portions extend from the first portion toward the first ends so as to be connected to the first ends.

The trench connection structure 90 on the other side has a first portion extending in the second direction Y, and a plurality of (two, in the present embodiment) second portions extending in the first direction X. The first portion faces the second ends of the plurality of trench gate structures 70 in a plan view. The second portions extend from the first portion toward the second ends so as to be connected to the second ends. The trench connection structures 90 constitute one annular or ladder-shaped trench structure with the plurality of trench gate structures 70 in each block region 81.

Referring to FIG. 6, the trench connection structures 90 are formed at intervals from the bottom of the first semiconductor region 51 toward the first main surface 3, and face the first semiconductor region 51 with a portion of the second semiconductor region 52 interposed therebetween.

Referring to FIG. 7, the trench connection structures 90 may be formed with approximately the same width and approximately the same depth as the trench gate structures 70. Of course, the first portion and the second portions of the trench connection structures 90 may have different widths. For example, the second portions of the trench connection structures 90 may be formed to have a narrower width than the first portion of the trench connection structures 90.

In this case, the first portion may have a width approximately equal to the width of the first trench isolation structure 60, and the second portions may have a width approximately equal to the width of the trench gate structures 70. Further in this case, the first portion may have a depth approximately equal to the depth of the first trench isolation structure 60, and the second portions may have a depth approximately equal to the depth of the trench gate structures 70.

Referring to FIG. 6, the trench connection structure 90 on the other side has a similar structure to the trench connection structure 90 on one side, except that it is connected to the second ends of the trench gate structure 70. Hereinafter, the configuration of the trench connection structure 90 on one side will be described, and description of the configuration of the trench connection structure 90 on the other side will be omitted.

Referring to FIG. 7 and FIGS. 11 to 13, the trench connection structure 90 includes a connection trench 91, a connection insulating film 92, and a connection electrode 93. The connection trench 91 is formed on the first main surface 3 to define a wall surface of the trench connection structure 90. The connection trench 91 is connected to the plurality of gate trenches 71.

The connection insulating film 92 covers a wall surface of the connection trench 91. The connection insulating film 92 is connected to the upper insulating film 76, the lower insulating film 77, and the intermediate insulating film 75 at a communication portion between the connection trench 91 and the gate trench 71. The connection insulating film 92 is thicker than the upper insulating film 76. A thickness of the connection insulating film 92 may be approximately equal to the thickness of the lower insulating film 77. The connection insulating film 92 may include a silicon oxide film. The connection insulating film 92 may include a silicon oxide film made of the oxide of the semiconductor chip 2, or may include a silicon oxide film formed by a CVD method.

The connection electrode 93 is buried in the connection trench 91 with the connection insulating film 92 interposed therebetween, and faces the second semiconductor region 52 and the first body region 67 across the connection insulating film 92. The connection electrode 93 is connected to the lower electrode 74 at a communication portion between the connection trench 91 and the gate trench 71, and is electrically insulated from the upper electrode 73 by the intermediate insulating film 75. The connection electrode 93 is constituted by a drawn-out portion in which the lower electrode 74 is drawn out from the inside of the gate trench 71 into the connection trench 91. The connection electrode 93 may contain conductive polysilicon.

Referring to FIGS. 9 and 10, the semiconductor device 1 includes a main surface insulating film 94 that selectively covers the first main surface 3 in the output region 6. The main surface insulating film 94 is connected to the insulating film 72 (upper insulating film 76) and the connecting insulating film 92, and exposes the first isolation electrode 63, the upper electrode 73, and the connection electrode 93.

Referring to FIGS. 9 and 10, the main surface insulating film 94 is thinner than the first isolation insulating film 62. The main surface insulating film 94 is thinner than the lower insulating film 77. The main surface insulating film 94 is thinner than the connection insulating film 92. The main surface insulating film 94 may have approximately the same thickness as the upper insulating film 76. The main surface insulating film 94 may include a silicon oxide film. The main surface insulating film 94 preferably includes a silicon oxide film made of the oxide of the semiconductor chip 2.

Referring to FIGS. 10 to 13, the semiconductor device 1 includes a field insulating film 95 that selectively covers the first main surface 3 inside and outside the output region 6. The field insulating film 95 is thicker than the main surface insulating film 94. The field insulating film 95 is thicker than the upper insulating film 76. The field insulating film 95 may have approximately the same thickness as the first isolation insulating film 62. The field insulating film 95 may include a silicon oxide film. The field insulating film 95 may include a silicon oxide film made of the oxide of the semiconductor chip 2, or may include a silicon oxide film formed by a CVD method.

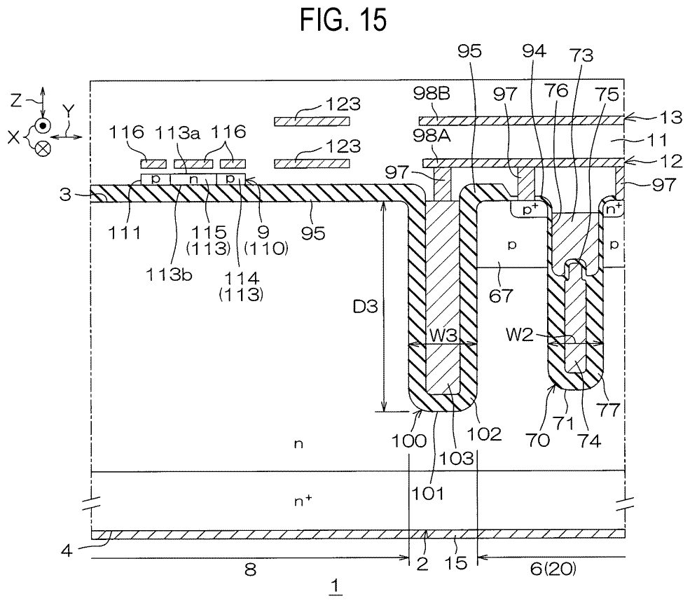

The field insulating film 95 covers the first main surface 3 along an inner wall of the first trench isolation structure 60 and an outer wall of a second trench isolation structure 100 (see FIG. 15, etc.) in the output region 6, and is connected to the first isolation insulating film 62, the connection insulating film 92, the main surface insulating film 94, and the second isolation insulating film 102 (see FIG. 15, etc.). The field insulating film 95 covers the first main surface 3 along an outer wall of the first trench isolation structure 60 outside the output region 6, and is connected to the first isolation insulating film 62.

Referring to FIGS. 9 to 13, the interlayer insulating layer 11 covers the first trench isolation structure 60, the trench gate structure 70, the trench connection structure 90, the main surface insulating film 94, and the field insulating film 95 in the output region 6.

Referring to FIG. 6, in the present embodiment, a plurality of block regions 81 are formed in the output region 6 on both sides of the inner element region 8 in the first direction X, respectively. The block regions 81 formed on one side of the inner element region 8 in the first direction X face the block regions 81 formed on the other side of the inner element region 8 in the first direction X across the inner element region 8 in the first direction X. The block regions 81 facing each other in the first direction X are electrically connected to each other.

Referring to FIG. 6, as described above, the semiconductor device 1 includes a plurality of gate wirings 16 arranged within the interlayer insulating layer 11. The gate wirings 16 are routed to the output region 6 and the control region 7. The gate wirings 16 are electrically connected to the output transistor 20 in the output region 6, and are electrically connected to the control circuit 23 (gate control circuit 24) (see FIG. 4) in the control region 7. The gate wirings 16 individually transmit a plurality of gate signals generated by the control circuit 23 (gate control circuit 24) (see FIG. 4) to the output transistor 20.

The gate wirings 16 include a first system gate wiring 16A and a second system gate wiring 16B. The first system gate wiring 16A individually transmits gate signals to the first system transistors 21A. The first system gate wiring 16A is electrically connected to the trench gate structures 70 for the first system transistor 21A via a plurality of via electrodes 97 arranged in the interlayer insulating layer 11. Specifically, the first system gate wiring 16A is electrically connected to the corresponding upper electrodes 73 and the corresponding connection electrodes 93 via the via electrodes 97.

That is, the upper electrode 73 and the lower electrode 74 for the first system transistor 21A are simultaneously controlled to be turned on and off by the same gate signal. This suppresses a voltage drop between the upper electrode 73 and the lower electrode 74, and suppresses undesired electric field concentration. As a result, a decrease in a withstand voltage (breakdown voltage) otherwise caused by the electric field concentration is suppressed.

The second system gate wiring 16B is electrically independent from the first system gate wiring 16A, and individually transmits a gate signal to the second system transistor 21B. The second system gate wiring 16B is electrically connected to the trench gate structures 70 for the second system transistor 21B via the via electrodes 97 arranged in the interlayer insulating layer 11. Specifically, the second system gate wiring 16B is electrically connected to the corresponding upper electrodes 73 and the corresponding connection electrodes 93 via the via electrodes 97.

That is, the upper electrode 73 and the lower electrode 74 for the second system transistor 21B are simultaneously controlled to be turned on and off by the same gate signal. This suppresses the voltage drop between the upper electrode 73 and the lower electrode 74, and suppresses undesired electric field concentration. As a result, a decrease in a withstand voltage (breakdown voltage) otherwise caused by the electric field concentration is suppressed.

Referring to FIGS. 10 to 13, the gate wirings 16 includes a first gate wiring 161 included in the first wiring layer 12 and a second gate wiring 162 included in the second wiring layer 13. The first gate wiring 161 may include a first system gate wiring 16A and a second system gate wiring 16B. The second gate wiring 162 may include a first system gate wiring 16A and a second system gate wiring 16B.

Referring to FIGS. 9 to 13, the semiconductor device 1 includes source wirings 98 disposed within the interlayer insulating layer 11. The source wirings 98 are electrically connected to the source terminal 17, the first trench isolation structure 60, and the channel cells 78. Specifically, the source wirings 98 are electrically connected to the first trench isolation structure 60 and the channel cells 78 via the via electrodes 97 arranged in the interlayer insulating layer 11.

Referring to FIG. 7, the via electrode 97 for each channel cell 78 is arranged so as to straddle two adjacent channel cells 78, and is formed in a band shape extending along each channel cell 78 in a plan view. Thus, the source terminal 17 is electrically connected to the system sources of all the system transistors 21 (unit sources of the unit transistors 22).

Referring to FIGS. 9 to 13, the source wirings 98 include a first source wiring (first output wiring) 98A included in first wiring layer 12 and a second source wiring (second output wiring) 98B included in the second wiring layer 13. The first source wiring 98A and the second source wiring 98B are electrically connected via a via electrode (not shown). A plurality of first source wirings 98A and a plurality of second source wirings 98B are formed so as to, in a plan view, overlap with substantially the entire region of the first main surface 3 where the output transistor 20 is formed.

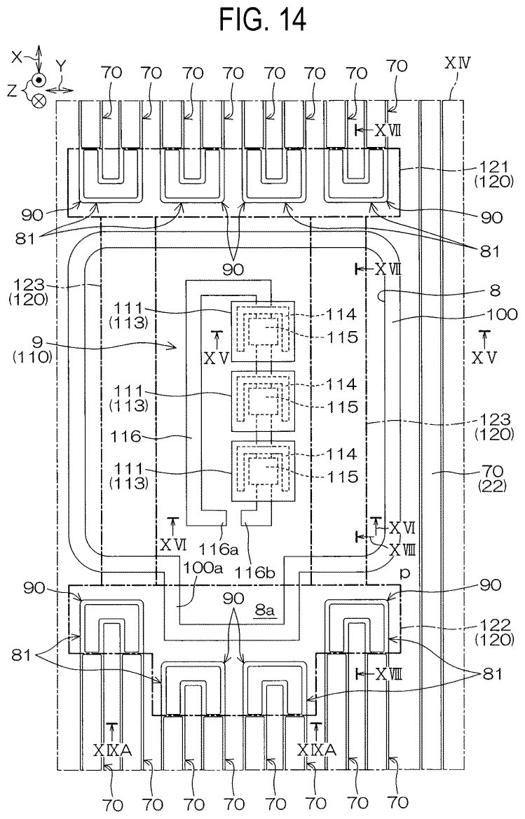

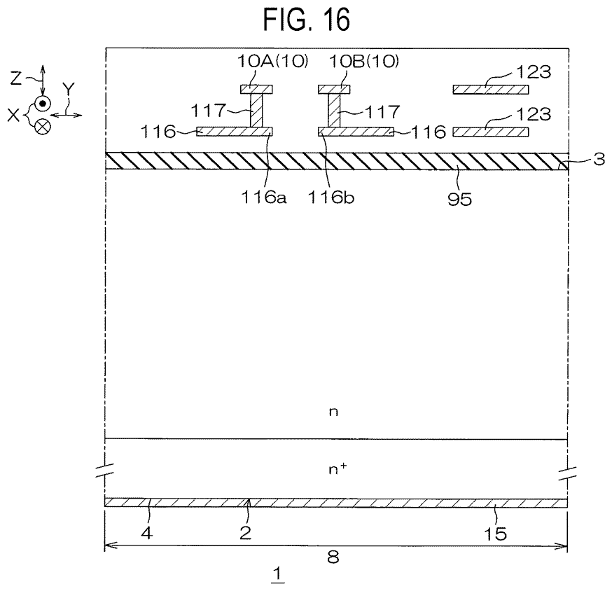

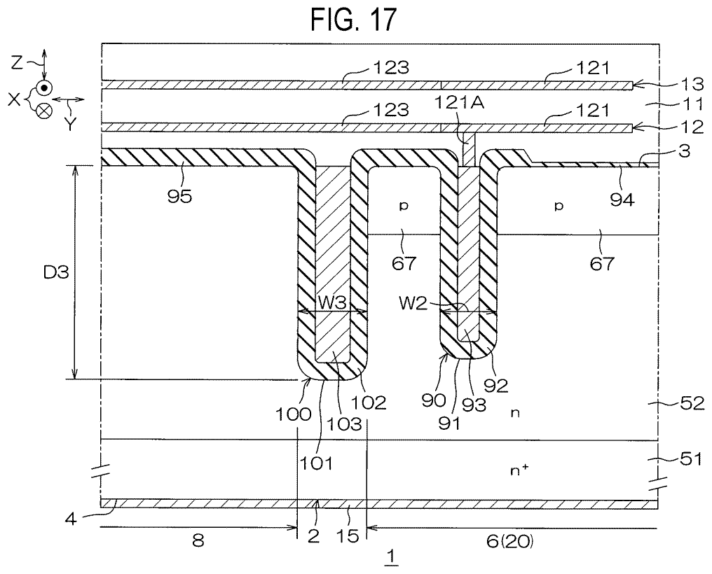

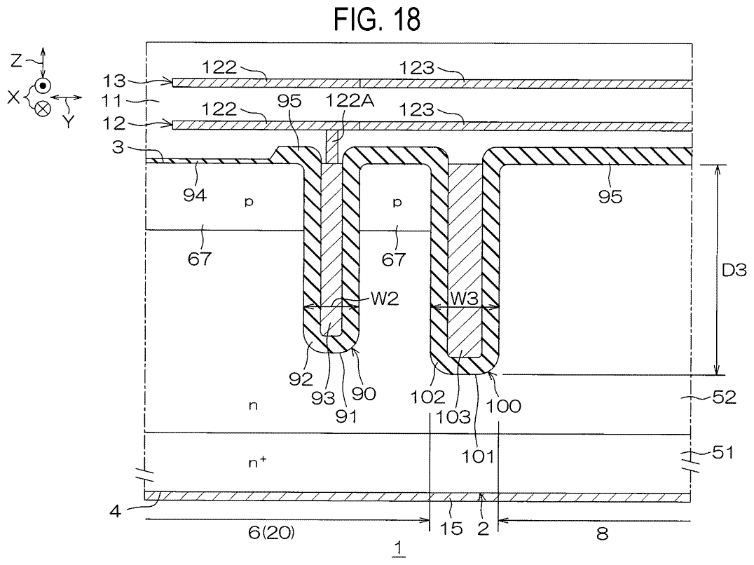

FIG. 14 is a plan view showing the inner element region 8, and is an enlarged view of region XIV shown in FIG. 6. FIG. 15 is a cross-sectional view taken along line XV-XV shown in FIG. 14. FIG. 16 is a cross-sectional view taken along line XVI-XVI shown in FIG. 14. FIG. 17 is a cross-sectional view taken along line XVII-XVII shown in FIG. 14. FIG. 18 is a cross-sectional view taken along line XVIII-XVIII shown in FIG. 14.

As described above, on the first main surface 3, the inner element region 8 surrounded by the output region 6 is formed in the central portion of the output region 6. A configuration of the inner element region 8 will be described below with reference to FIGS. 6, 14, 15 and 17.

Referring to FIGS. 6 and 14, the inner element region 8 is a region insulated and isolated from the output region 6. In the present embodiment, the inner element region 8 is defined in a polygonal shape having four sides parallel to the peripheral edges of the first main surface 3 in a plan view. In the example of FIGS. 6 and 14, the inner element region 8 has a substantially rectangular shape. The inner element region 8 has a protrusion 8a protruding outward in the first direction X in a region facing the control region 7 across the output region 6.

Referring to FIG. 14, the semiconductor device 1 includes a second trench isolation structure (isolation structure) 100 (trench separation structure) as an example of a region isolation structure that defines the outer periphery of the inner element region 8 on the first main surface 3. The second trench isolation structure 100 may be referred to as a “deep trench isolation (DTI) structure.” The second trench isolation structure 100 may be referred to as an “inner isolation structure.”

Referring to FIG. 14, the second trench isolation structure 100 is formed in an annular shape surrounding the outer periphery of the inner element region 8 in a plan view. In the present embodiment, the second trench isolation structure 100 is formed in a substantially quadrangular and annular shape having four sides parallel to the peripheral edges of the first main surface 3 in a plan view. The second trench isolation structure 100 has a protrusion 100a that protrudes outward in the first direction X in a region facing the control region 7 across the output region 6. A planar shape of the second trench isolation structure 100 is arbitrary, and may be formed in a polygonal ring shape.

Referring to FIGS. 15 and 17, the second trench isolation structure 100 includes a second isolation trench (isolation trench) 101, a second isolation insulating film (isolation insulator) 102, and a second isolation electrode (isolation electrode) 103. That is, the second trench isolation structure 100 has a single electrode structure including a single electrode (second isolation electrode 103) buried in the second isolation trench 101 with the insulator (second isolation insulating film 102) interposed therebetween.

Referring to FIGS. 15 and 17, the second isolation trench 101 is dug down from the first main surface 3 toward the second main surface 4. The second isolation trench 101 is formed at an interval from the bottom of the second semiconductor region 52 toward first main surface 3. The second isolation insulating film 102 covers a wall surface of the second isolation trench 101. The second isolation insulating film 102 may include a silicon oxide film. The second isolation insulating film 102 may include a silicon oxide film made of the oxide of the semiconductor chip 2, or may include a silicon oxide film formed by a CVD method. The second isolation electrode 103 is buried in the second isolation trench 101 with the second isolation insulating film 102 interposed therebetween. The second isolation electrode 103 may contain conductive polysilicon.

Referring to FIGS. 15 and 17, the second trench isolation structure 100 has a second isolation width W3 and a second isolation depth D3. The second isolation depth D3 may be the same as the first isolation depth D1 (D3=D1). The second isolation depth D3 preferably exceeds the trench depth D2 (D3>D2). The second isolation width W3 is a width in a direction perpendicular to a direction in which the second trench isolation structure 100 extends in a plan view. The second isolation width W3 may be the same as the first isolation width W1 (W3=W1).

An aspect ratio D3/W3 of the second trench isolation structure 100 may be greater than 1 and less than or equal to 5. The aspect ratio D3/W3 is a ratio of the second isolation depth D3 to the second isolation width W3. The aspect ratio D3/W3 is preferably 2 or more. The bottom wall of the second trench isolation structure 100 is preferably spaced apart from the bottom of the second semiconductor region 52 by 1 μm or more and 5 μm or less.

Referring to FIG. 14, the second trench isolation structure 100 has a corner portion that connects portions extending in the first direction X and the second direction Y in an arc shape (curved shape). In the present embodiment, the four corners of the second trench isolation structure 100 are formed in an arc shape. In other words, the inner element region 8 is defined in a substantially quadrangular shape having four corners each extending in an arc shape. It is preferable that the corners of the second trench isolation structure 100 have a constant second isolation width W3 along an arc direction.

Referring to FIGS. 15 and 17, the second isolation trench 101 includes sidewalls and a bottom wall. An angle between a sidewall of the second isolation trench 101 and the first main surface 3 within the semiconductor chip 2 may be 90 degrees or more and 92 degrees or less. The second isolation trench 101 may be formed in a tapered shape in which an opening width grows smaller from the opening toward the bottom wall. Bottom wall corners of the second isolation trench 101 are preferably formed in a curved shape. The entire bottom wall of the second isolation trench 101 may be formed in a bulging shape toward the second main surface 4.

Referring to FIGS. 15 and 17, the second isolation insulating film 102 is formed on the wall surface of the second isolation trench 101. Specifically, the second isolation insulating film 102 is formed in the form of a film over the entire wall surface of the second isolation trench 101, and defines a recess space within the second isolation trench 101. The second isolation insulating film 102 preferably includes a silicon oxide film. It is particularly preferable that the second isolation insulating film 102 includes a silicon oxide film made of the oxide of the semiconductor chip 2.

Referring to FIGS. 15 and 17, the second isolation electrode 103 is buried as an integrated member in the second isolation trench 101 with the second isolation insulating film 102 interposed therebetween. In the present embodiment, the second isolation electrode 103 is made of conductive polysilicon. A source potential is applied to the second isolation electrode 103. The second isolation electrode 103 has an electrode surface (isolation electrode surface) exposed from the second isolation trench 101. The electrode surface of the second isolation electrode 103 may be recessed in a curved shape toward the bottom wall of the second isolation trench 101. The electrode surface of the second isolation electrode 103 is preferably spaced apart from the first main surface 3 to the bottom wall of the second isolation trench 101 in the depth direction of the second isolation trench 101.

Referring to FIGS. 15 and 17, the field insulating film 95 covers the first main surface 3 in the inner element region 8. The field insulating film 95 covers the first main surface 3 along an inner wall of the second trench isolation structure 100 in the inner element region 8 and is connected to the second isolation insulating film 102.

As described above, the temperature sensor element 9 is arranged in the inner element region 8. A configuration of the temperature sensor element 9 will be described below with reference to FIGS. 14 and 15.

Referring to FIGS. 14 and 15, in the present embodiment, the temperature sensor element 9 is a temperature sensing diode 110. The temperature sensing diode 110 is, for example, a polysilicon diode. The temperature sensing diode 110 includes a plurality of temperature sensing diode elements 111. The temperature sensing diode 110 is in the form of a diode array in which a plurality of temperature sensing diode elements 111 are connected in series in the forward direction. Although not shown, in the temperature sensing diode 110, the temperature sensing diode elements 111 may be connected in parallel. Further, the number of temperature sensing diode elements 111 included in the temperature sensing diode 110 may be, for example, two to four (three in the example of FIG. 14). In addition, the number of temperature sensing diode elements 111 included in the temperature sensing diode 110 is not limited to the plural number but may be one.

Referring to FIG. 15, each temperature sensing diode element 111 includes a polysilicon layer 113 formed over the first main surface 3 in the inner element region 8. More specifically, the polysilicon layer 113 is formed over the field insulating film 95. The polysilicon layer 113 is electrically insulated from the first main surface 3 by the field insulating film 95. A thickness of the polysilicon layer 113 may be 0.2 μm or more and 1.0 μm or less. The temperature sensing diode element 111 is formed by selectively introducing n-type impurities and p-type impurities into the polysilicon layer 113. The temperature sensing diode element 111 includes an anode region 114 formed in the polysilicon layer 113 and a cathode region 115 formed in the polysilicon layer 113. The temperature sensing diode element 111 is a diode element having the anode region 114 as an anode and the cathode region 115 as a cathode.

Referring to FIG. 14, each polysilicon layer 113 is formed to have a quadrangular shape in a plan view. A plurality of polysilicon layers 113 are arranged in the first direction X. The cathode region 115 is formed in the central portion of the polysilicon layer 113. In the present embodiment, the cathode region 115 is exposed from the first surface 113a and the second surface 113b of the polysilicon layer 113.

Referring to FIG. 14, the anode region 114 is formed along the peripheral edge of the cathode region 115. In the present embodiment, the anode region 114 is formed in a C-shape or a U-shape surrounding the cathode region 115 in a plan view. The anode region 114 may be formed in an annular shape surrounding the entire circumference of the cathode region 115. The anode region 114 is electrically connected to the cathode region 115. In the present embodiment, the anode region 114 is exposed from the first surface 113a and the second surface 113b of the polysilicon layer 113. The anode region 114 is connected to the cathode region 115 over the entire thickness of the polysilicon layer 113. The anode region 114 forms a pn junction at an interface with the cathode region 115. In the present embodiment, since the anode region 114 surrounds the cathode region 115 in a C-shape or a U-shape, the pn junction also has a C-shape or a U-shape in a plan view. The anode region 114 may annularly surround the cathode region 115. In this case, the pn junction has an annular shape in a plan view.

Referring to FIGS. 14 and 16, the temperature sensing diode 110 includes a diode wiring 116. The diode wiring 116 has one end 116a and the other end 116b. The first connection wiring 10A is electrically connected to the one end 116a of the diode wiring 116 via a via electrode 117. The second connection wiring 10B is electrically connected to the other end 116b of the diode wiring 116 via the via electrode 117. Therefore, the temperature sensor element 9 (temperature sensing diode 110) is connected to the control circuit 23 (see FIG. 4) in the control region 7 via the first connection wiring 10A and the second connection wiring 10B.

Referring to FIG. 14, a pair of block regions 81 facing each other in the first direction X across the inner element region 8 are electrically connected to each other. The connection electrodes 93 (see FIGS. 17 and 18) in the block regions 81 are connected by gate connection wirings 120. The gate connection wirings 120 include a first gate connection wiring 121 and a second gate connection wiring 122 facing each other in the first direction X.

Referring to FIG. 14, the first gate connection wiring 121 has a band shape extending in the second direction Y. The first gate connection wiring 121 is formed so as to overlap with the block region 81 on one side (an upper side in FIG. 14) in the first direction X in a plan view.

Referring to FIG. 17, the first gate connection wiring 121 is electrically connected to the connection electrode 93 in the block region 81 via a via electrode 121A.

Referring to FIG. 14, the second gate connection wiring 122 has a band shape extending in the second direction Y. The second gate connection wiring 122 is formed so as to overlap with the block region 81 on the other side (a lower side in FIG. 14) in the first direction X in a plan view.

Referring to FIG. 18, the second gate connection wiring 122 is electrically connected to the connection electrode 93 in the block region 81 via a via electrode 122A.

As described above, in the present embodiment, the protrusion 8a is formed in the inner element region 8. Referring to FIG. 14, in order to avoid an interference with the protrusion 8a, on the first main surface 3, the trench connection structure 90 facing the protrusion 8a in the first direction X is retracted more outward (toward the control region 7) in the first direction X than the other trench connection structures 90. The second gate connection wiring 122 is arranged so as to overlap with all the connection electrodes 93 (trench connection structures 90) in the block region 81 on the other side in the normal direction Z. The second gate connection wiring 122 crosses the protrusion 8a of the inner element region 8 in the second direction Y in a plan view.

Referring to FIG. 14, the gate connection wiring 120 further includes a third gate connection wiring 123. The third gate connection wiring 123 electrically connects the first gate connection wiring 121 and the second gate connection wiring 122. The third gate connection wiring 123 has a band shape extending in the first direction X. In the present embodiment, the third gate connection wiring 123 has a pair of third gate connection wirings 123 facing each other in the second direction Y. The third gate connection wirings 123 cross the inner element region 8 in the first direction X in a plan view. A pair of the third gate connection wirings 123 sandwich the temperature sensor element 9 in the second direction Y in a plan view. The number of third gate connection wirings 123 is not limited to one pair (two), and may be one.

Referring to FIGS. 17 and 18, the gate connection wiring 120 includes a lower wiring included in the first wiring layer 12 and an upper wiring included in the second wiring layer 13. Specifically, the first gate connection wiring 121 (see FIG. 17) includes a first gate connection wiring 121 included in the first wiring layer 12 and a first gate connection wiring 121 included in the second wiring layer 13. The second gate connection wiring 122 (see FIG. 18) includes a second gate connection wiring 122 included in the first wiring layer 12 and a second gate connection wiring 122 included in the second wiring layer 13. The third gate connection wiring 123 (see FIGS. 17 and 18) includes a third gate connection wiring 123 included in the first wiring layer 12 and a third gate connection wiring 123 included in the second wiring layer 13. The first gate connection wiring 121, the second gate connection wiring 122, and the third gate connection wiring 123 included in the first wiring layer 12 are electrically connected to the first gate connection wiring 121, the second gate connection wiring 122, and the third gate connection wiring 123 included in the second wiring layer 13 via vias (not shown), respectively.

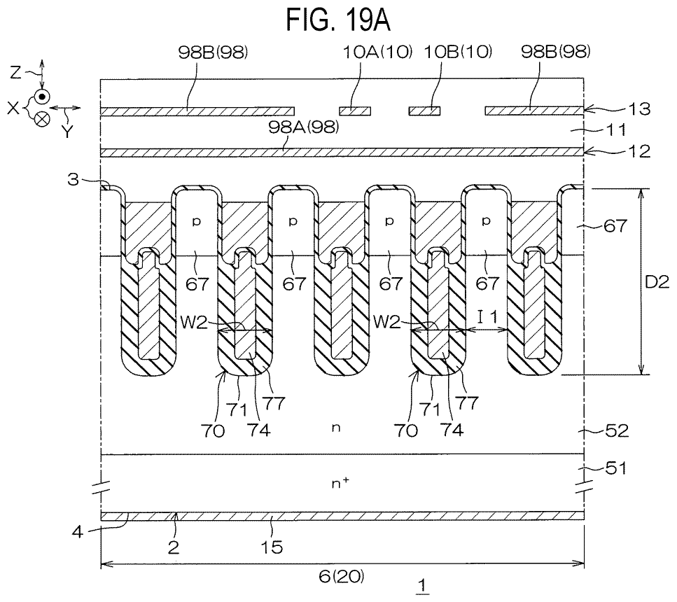

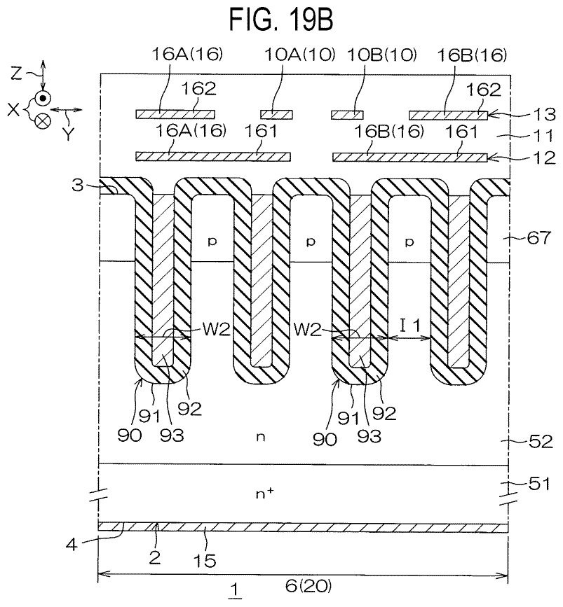

FIG. 19A is a cross-sectional view taken along line XIXA-XIXA shown in FIG. 14. FIG. 19B is a cross-sectional view taken along line XIXB-XIXB shown in FIG. 6.

Referring to FIG. 19A, in a region between the control region 7 and the inner element region 8 in the output region 6, the first source wiring 98A and the second source wiring 98B are arranged above the first main surface 3. As described above, the first source wiring 98A is included in the first wiring layer 12, and the second source wiring 98B is included in the second wiring layer 13. In this region, the second wiring layer 13 includes the first connection wiring 10A and the second connection wiring 10B, as well as the second source wiring 98B. In this region, the first connection wiring 10A and the second connection wiring 10B extend along the first direction X. The first connection wiring 10A and the second connection wiring 10B are sandwiched by the plurality of second source wirings 98B in the second direction Y. The first source wiring 98A overlaps with the first connection wiring 10A and the second connection wiring 10B in the normal direction Z.

The first connection wiring 10A and the second connection wiring 10B are not included in the first wiring layer 12. The first connection wiring 10A and the second connection wiring 10B are insulated and isolated from each other. The first connection wiring 10A and the second connection wiring 10B are insulated and isolated from the second source wiring 98B. The first connection wiring 10A and the second connection wiring 10B are also insulated and isolated from the first source wiring 98A included in the first wiring layer 12.

The first source wiring 98A is formed so as to overlap with the entire region in which the output transistor 20 is arranged on the first main surface 3 in a plan view. The second source wiring 98B is formed so as to overlap with the entire region in which the output transistor 20 is formed on the first main surface 3 in a plan view, except for a region in which the connection wirings 10 (the first connection wiring 10A and the second connection wiring 10B) are arranged.

The trench gate structure 70 is arranged below the first connection wiring 10A and the second connection wiring 10B. That is, the trench gate structure 70 is formed below the first connection wiring 10A and the second connection wiring 10B so as to overlap with the first connection wiring 10A and the second connection wiring 10B in a plan view.

In the present embodiment, the first connection wiring 10A and the second connection wiring 10B are included in the wiring layer (second wiring layer 13). Therefore, even when the output transistor 20 is arranged so as to overlap with the first connection wiring 10A and the second connection wiring 10B in a plan view, the output transistor 20 and the connection wirings 10A and 10B are not electrically connected. In this case, since the first connection wiring 10A and the second connection wiring 10B can be arranged above the trench gate structure 70, the output transistor 20 can be arranged on substantially the entire circumference of the quadrangular and annular output region 6 surrounding the entire circumference of the inner element region 8.

Referring to FIG. 19B, in a region between the control region 7 and the inner element region 8 in the output region 6, the first gate wiring 161 and the second gate wiring 162 are arranged above the first main surface 3. As described above, the first gate wiring 161 is included in the first wiring layer 12, and the second gate wiring 162 is included in the second wiring layer 13. In this region, the second wiring layer 13 includes the second gate wiring 162, the first connection wiring 10A, and the second connection wiring 10B. The first connection wiring 10A and the second connection wiring 10B are not included in the first wiring layer 12. In this region, the first connection wiring 10A and the second connection wiring 10B extend along the first direction X, just like the first gate wiring 161 and the second gate wiring 162.

The first connection wiring 10A and the second connection wiring 10B are insulated and isolated from each other. The first connection wiring 10A and the second connection wiring 10B are insulated and isolated from the second gate wiring 162. The first connection wiring 10A and the second connection wiring 10B are also insulated and isolated from the first gate wiring 161 included in the first wiring layer 12.

Referring to FIGS. 3, 4, 19A and 19B, a first temperature detection signal from the temperature sensor element 9 is given to the overheat protection circuit 27 via the first connection wiring 10A and the second connection wiring 10B. The overheat protection circuit 27 controls the on/off operation of the output transistor 20 based on the first temperature detection signal from the temperature sensor element 9. When it is determined that the output region 6 is in an overheated state, the overheat protection circuit 27 controls a part or all of the output transistor 20 to be turned off. This prevents the semiconductor device 1 from being destroyed.

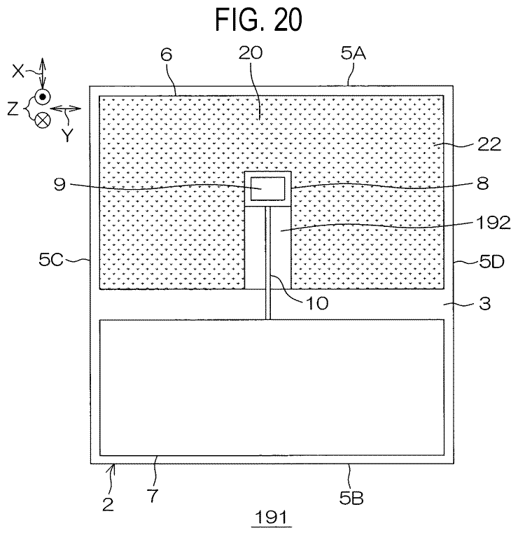

FIG. 20 is a plan view showing an example of a layout inside a semiconductor chip 2 of a semiconductor device 191 according to a reference embodiment. In FIG. 20, the output region 6 is formed to surround the inner element region 8. However, in the reference embodiment shown in FIG. 20, the output transistor 20 is not arranged in a region 192 between the control region 7 and the inner element region 8 in the output region 6. That is, in the reference embodiment shown in FIG. 20, the output transistor 20 is not arranged in the region in the output region 6 that overlaps with the connection wiring 10 in a plan view (the region below the connection wiring 10 in the output region 6).

In the semiconductor device 1 according to the first embodiment, as shown in FIG. 19A, the transistor 20 is also formed in the entire region between the control region 7 and the inner element region 8 in the output region 6 in the second direction Y. That is, the output transistor 20 is also formed in a region of the output region 6 that overlaps with the connection wiring 10 in a plan view. By effectively utilizing this region as an arrangement region for the output transistor 20, the semiconductor device 1 can increase mounting efficiency for the output transistor 20 on the first main surface 3 as compared with the reference embodiment shown in FIG. 20. Thus, in the semiconductor device 1, it is possible to reduce a chip area.

Further, the first connection wiring 10A and the second connection wiring 10B included in the first wiring layer 12 are not included in the first wiring layer 12 but are included in the second wiring layer 13 formed over the first wiring layer 12. Thus, routing of the first source wiring 98A in the first wiring layer 12 is not affected. Therefore, a source potential can be satisfactorily applied to the output transistor 20 (unit transistors 22). As a result, the mounting efficiency of the output transistor 20 can be improved while satisfactorily applying the source potential to the output transistor 20.

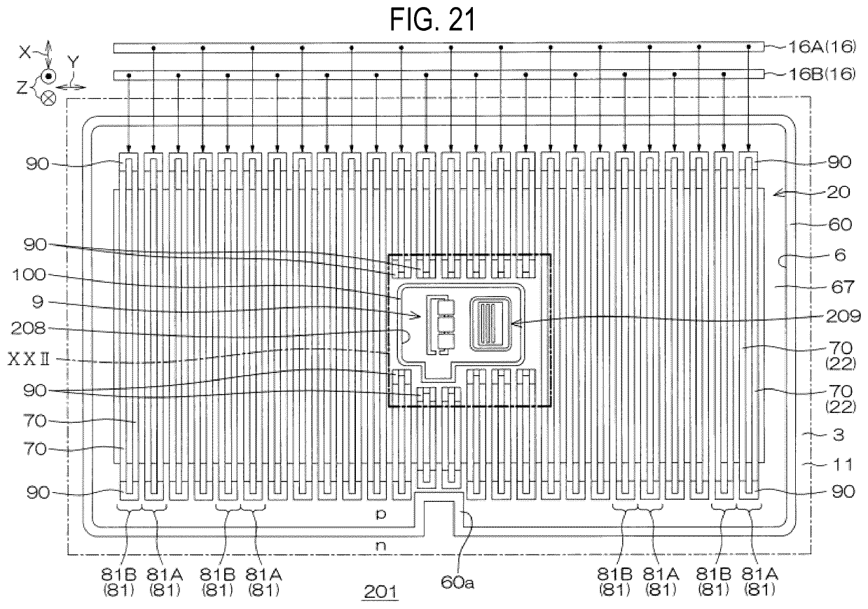

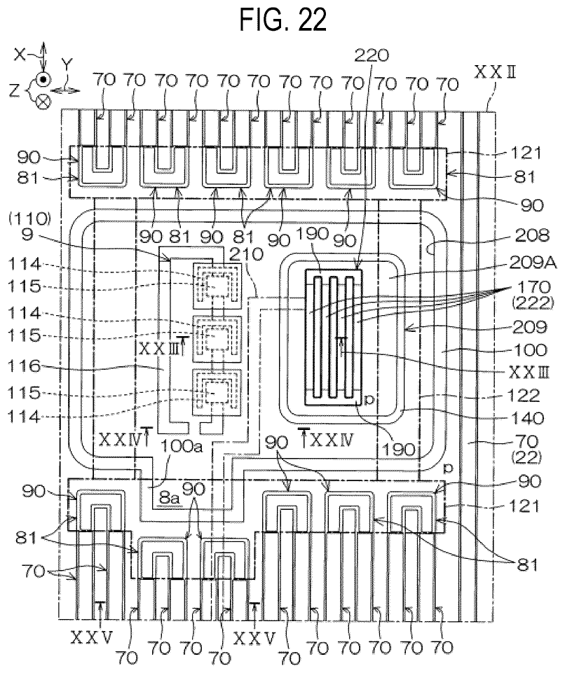

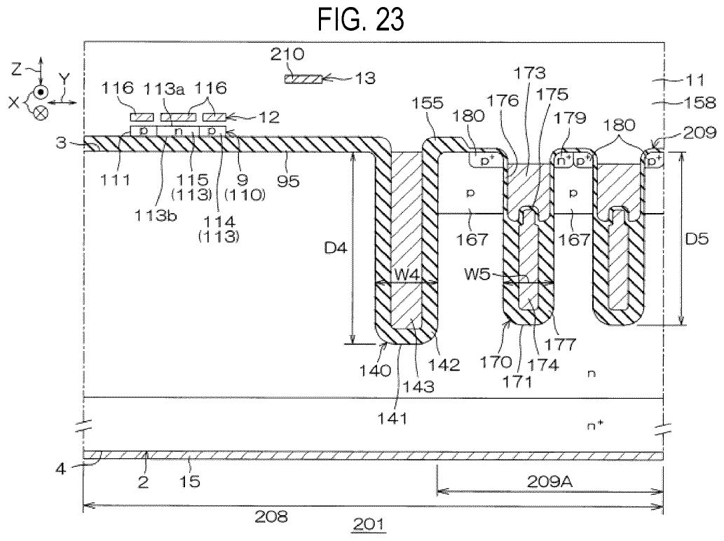

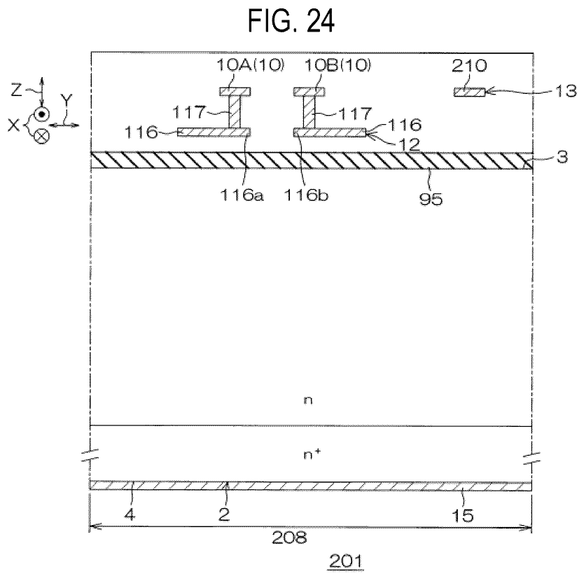

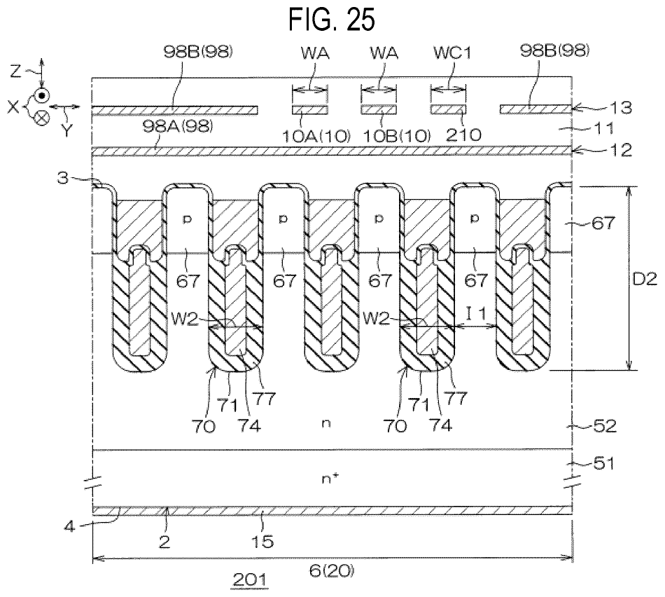

FIG. 21 is a plan view showing an output region 6 and an inner element region 208 of a semiconductor device 201 according to a second embodiment of the present disclosure, and is a view corresponding to FIG. 6. FIG. 22 is a plan view showing an inner element region 208, and is an enlarged view of region XXII shown in FIG. 21. FIG. 23 is a cross-sectional view taken along line XXIII-XXIII shown in FIG. 22. FIG. 24 is a cross-sectional view taken along line XXIV-XXIV shown in FIG. 22. FIG. 25 is a cross-sectional view taken along line XXV-XXV shown in FIG. 22. In the second embodiment, only the parts that are different from those of the first embodiment will be mainly described. The same configurations as those described so far will be designated by the same reference numerals and the description thereof will be omitted.

The second embodiment differs from the first embodiment in that not only the temperature sensor element 9 as the first element but also a current monitor element 209 as the second element is arranged in the inner element region 208. Another difference between the second embodiment and the first embodiment is that a third trench isolation structure 140 (see FIG. 22) is formed inside the inner element region 208.

Referring to FIGS. 21 and 22, the inner element region 208 is larger in size in the second direction Y than the inner element region 8 (see FIGS. 6 and 14). Except for this point, the inner element region 208 has the same configuration as the inner element region 8. The outer periphery of the inner element region 208 is defined by the second trench isolation structure 100 just like the inner element region 8.

As described above, the temperature sensor element 9 and the current monitor element 209 as an example of the second element are arranged in the inner element region 208. The inner element region 208 is arranged side by side with the temperature sensor element 9 in the second direction Y.

In the semiconductor device 201 according to the second embodiment, the current monitor element 209 generates a monitor current for monitoring the output current Io of the output transistor 20 (see FIG. 4). The current monitor element 209 includes a transistor having the same configuration as the output transistor 20, and is controlled to be turned on and off simultaneously with the output transistor 20 to generate a monitor current linked to the output current Io.

The current monitor element 209 is used in place of the current monitor circuit 25 (see FIG. 4) of the control circuit 23 of the first embodiment. The overcurrent protection circuit 26 (see FIG. 4) generates an electric signal to control the gate control circuit 24 based on the monitor current from the current monitor element 209, and controls the on/off operation of the output transistor 20 in cooperation with the gate control circuit 24.

A configuration of the current monitor element 209 will be described below with reference to FIGS. 22 to 25.

Referring to FIG. 22, the third trench isolation structure 140 defines a current detection region 209A where the current monitor element 209 is arranged in the inner element region 208. The third trench isolation structure 140 may be referred to as a “DTI structure.” In the present embodiment, the third trench isolation structure 140 is formed in a quadrangular and annular shape having four sides parallel to the peripheral edges of the first main surface 3 in a plan view, and defines a current detection region 209A having a quadrangular shape. The current detection region 209A may be defined in a polygonal shape according to a planar shape of the third trench isolation structure 140. In this case, the planar shape of the third trench isolation structure 140 may be formed in a polygonal and annular shape.

Referring to FIG. 23, the third trench isolation structure 140 includes a third isolation trench 141, a third isolation insulating film 142, and a third isolation electrode 143. That is, the third trench isolation structure 140 has a single electrode structure including a single electrode (third isolation electrode 143) buried in the third isolation trench 141 with an insulator (third isolation insulating film 142) interposed therebetween.

The third isolation trench 141 is dug down from the first main surface 3 toward the second main surface 4. The third isolation trench 141 is formed at an interval from the bottom of the second semiconductor region 52 toward the first main surface 3. The third isolation insulating film 142 covers a wall surface of the third isolation trench 141. The third isolation insulating film 142 may include a silicon oxide film. The third isolation insulating film 142 may include a silicon oxide film made of the oxide of the semiconductor chip 2, or may include a silicon oxide film formed by a CVD method. The third isolation electrode 143 is buried in the third isolation trench 141 with the third isolation insulating film 142 interposed therebetween. The third isolation electrode 143 may contain conductive polysilicon.

An aspect ratio D4/W4 of the third trench isolation structure 140 may be greater than 1 and less than or equal to 5. The aspect ratio D4/W4 is a ratio of a third isolation depth D4 to a third isolation width W4. The aspect ratio D4/W4 is preferably 2 or more. The bottom wall of the third trench isolation structure 140 is preferably spaced apart from the bottom of the second semiconductor region 52 by 1 μm or more and 5 μm or less.

Referring to FIG. 23, the third isolation trench 141 includes sidewalls and a bottom wall. An angle between a sidewall of the third isolation trench 141 and the first main surface 3 within the semiconductor chip 2 may be 90 degrees or more and 92 degrees or less. The third isolation trench 141 may be formed in a tapered shape in which an opening width grows smaller from the opening toward the bottom wall. Bottom wall corners of the third isolation trench 141 are preferably formed in a curved shape. The entire bottom wall of the third isolation trench 141 may be formed in a curved shape toward the second main surface 4.

Referring to FIG. 23, the third isolation insulating film 142 is formed on the wall surface of the third isolation trench 141. Specifically, the third isolation insulating film 142 is formed in a film shape over the entire wall surface of the third isolation trench 141, and defines a recess space within the third isolation trench 141. The third isolation insulating film 142 preferably includes a silicon oxide film. It is more preferable that the third isolation insulating film 142 includes a silicon oxide film made of the oxide of the semiconductor chip 2.

Referring to FIG. 23, the third isolation electrode 143 is buried as an integrated member in the third isolation trench 141 with the third isolation insulating film 142 interposed therebetween. In the present embodiment, the third isolation electrode 143 contains conductive polysilicon. A source potential is applied to the third isolation electrode 143. The third isolation electrode 143 has an electrode surface (isolation electrode surface) exposed from the third isolation trench 141. The electrode surface of the third isolation electrode 143 may be recessed in a curved shape toward the bottom wall of the third isolation trench 141. The electrode surface of the third isolation electrode 143 is preferably spaced apart from the first main surface 3 to the bottom wall of the third isolation trench 141 in the depth direction of the third isolation trench 141.

Referring to FIG. 23, the semiconductor device 201 includes a second body region 167 formed in the surface layer portion of the first main surface 3 in the current detection region 209A. The p-type impurity concentration of the second body region 167 may be 1×10¹⁶ cm⁻³ or more and 1×10¹⁸ cm⁻³ or less. The p-type impurity concentration of the second body region 167 is preferably approximately equal to the p-type impurity concentration of the first body region 67 (see FIG. 7, etc.). Preferably, the second body region 167 has approximately the same thickness (depth) as the first body region 67. According to this structure, the second body region 167 can be formed simultaneously with the first body region 67.

The second body region 167 is formed over the entire surface layer portion of the first main surface 3 in the current detection region 209A. The second body region 167 is in contact with the inner peripheral wall of the third isolation trench 141 and is not in contact with the inner peripheral wall of the second isolation trench 101.

Referring to FIG. 22, the semiconductor device 201 includes a monitor transistor 220 formed on the first main surface 3 in the current detection region 209A. The monitor transistor 220 includes a plurality of unit transistors 222 formed collectively on the first main surface 3 in the current detection region 209A. The unit transistors 222 are formed in a stripe shape extending in the first direction X in a plan view. In the monitor transistor 220, a monitor current corresponding to the output current Io (see FIG. 4) is generated in the second body region 167.

Referring to FIG. 23, each unit transistor 222 includes one trench gate structure 170 and a channel cell controlled by the trench gate structure 170. In the present embodiment, each unit transistor 222 includes a pair of channel cells formed on both sides of one trench gate structure 170. Each channel cell includes a plurality of n-type source regions 179 and a plurality of p-type contact regions 180.

The trench gate structures 170 are arranged at intervals in the second direction Y in a plan view, and are respectively formed in a band shape extending in the first direction X. That is, the trench gate structures 170 are formed in a stripe shape extending in the first direction X in a plan view.

Referring to FIG. 23, the trench gate structures 170 have a trench width W5 and a trench depth D5. The trench width W5 may be approximately equal to the trench width W2 (W5≈W2). The trench depth D5 may be approximately equal to the trench depth D2 (D5≈D2). An aspect ratio D5/W5 of the trench gate structure 170 may be equal to the aspect ratio D2/W2 of the trench gate structure 70.

The trench gate structure 170 includes a gate trench 171, an insulating film 172, an upper electrode 173, a lower electrode 174, and an intermediate insulating film 175. In other words, the trench gate structure 170 has a multi-electrode structure including a plurality of electrodes (the upper electrode 173 and the lower electrode 174) buried vertically in the gate trench 171 with the insulators (the insulating film 172 and the intermediate insulating film 175) interposed therebetween. The insulating film 172 includes an upper insulating film 176 and a lower insulating film 177. The gate trench 171, the insulating film 172, the upper electrode 173, the lower electrode 174, the intermediate insulating film 175, the upper insulating film 176, and the lower insulating film 177 have the same configurations as the gate trench 71, the insulating film 72, the upper electrode 73, the lower electrode 74, the intermediate insulating film 75, the upper insulating film 76, and the lower insulating film 77 shown in FIG. 9, etc.

The first and second ends of each of the trench gate structures 170 are connected by a trench connection structure 190. A configuration of the trench connection structure 190 is the same as the trench connection structure 90 (see FIG. 7, etc.). Therefore, the description thereof will be omitted.

Referring to FIG. 23, the semiconductor device 201 includes a field insulating film 155 that selectively covers the first main surface 3 inside and outside the current detection region 209A. A thickness of the field insulating film 155 may be the same as that of the field insulating film 95 (see FIG. 9, etc.). The field insulating film 155 may include a silicon oxide film. The field insulating film 155 may include a silicon oxide film made of the oxide of the semiconductor chip 2, or may include a silicon oxide film formed by a CVD method.

The monitor transistor 220 is controlled to be turned on and off at the same timing as the output transistor 20. The monitor transistor 220 generates a monitor current that increases or decreases in conjunction with the output current Io of the output transistor 20 (see FIG. 4). The monitor current generated by the monitor transistor 220 is provided to the overcurrent protection circuit 26 (see FIG. 4) of the control circuit 23 in the control region 7 via the connection wiring 210.

The monitor transistor 220 may include a first system monitor transistor and a second system monitor transistor corresponding to the first system transistor 21A and the second system transistor 21B, respectively. Each system monitor transistor may be controlled to be turned on and off at the same timing as the corresponding system transistor 21A or 21B, and may respectively generate a system monitor current that increases or decreases in conjunction with the increase or decrease in the system current Is (see FIG. 4) of the corresponding system transistor 21A or 21B.

As shown in FIG. 22, one end of the connection wiring 210 is connected to the current monitor element 209. The connection wiring 210 is, for example, one wiring. The other end of the connection wiring 210 extends across the output region 6 from the inner element region 208 to the control region 7 outside the output region 6. The connection wiring 210 connects the current monitor element 209 and the control circuit 23 (see FIG. 4) of the control region 7.

As shown in FIGS. 23 and 24, the connection wiring 210 is included in the second wiring layer 13. The current signal from the current monitor element 209 is applied to the overcurrent protection circuit 26 (see FIG. 4) of the control circuit 23 via the connection wiring 210.

Referring to FIG. 25, in a region between the control region 7 and the inner element region 208 in the output region 6, the first source wiring 98A and the second source wiring 98B are arranged above the first main surface 3. As described above, the first source wiring 98A is included in the first wiring layer 12, and the second source wiring 98B is included in the second wiring layer 13. In this region, the second wiring layer 13 includes the connection wiring 210 as well as the second source wiring 98B, the first connection wiring 10A, and the second connection wiring 10B. In this region, the connection wiring 210 extends along the first direction X. The connection wiring 210 is sandwiched by a plurality of second source wirings 98B in the second direction Y. A wiring width WC1 of the connection wiring 210 is the same as a wiring width WA of each of the first connection wiring 10A and the second connection wiring 10B. The first source wiring 98A overlaps the connection wiring 210 in the normal direction Z.

The connection wiring 210 is not included in the first wiring layer 12. The connection wiring 210 is insulated and isolated from the first connection wiring 10A and the second connection wiring 10B. The connection wiring 210 is also insulated and isolated from the second source wiring 98B. The connection wiring 210 is also insulated and isolated from the first source wiring 98A included in the first wiring layer 12.

The current signal from the current monitor element 209 (see FIG. 22) is applied to the overcurrent protection circuit 26 (see FIG. 4) of the control circuit 23 via the connection wiring 210. The overcurrent protection circuit 26 controls the on/off operation of the output transistor 20 based on the current signal. When it is determined that the output region 6 is in an overcurrent state, the overcurrent protection circuit 26 controls a part or all of the output transistor 20 to be turned off. This prevents the semiconductor device 201 from being destroyed.

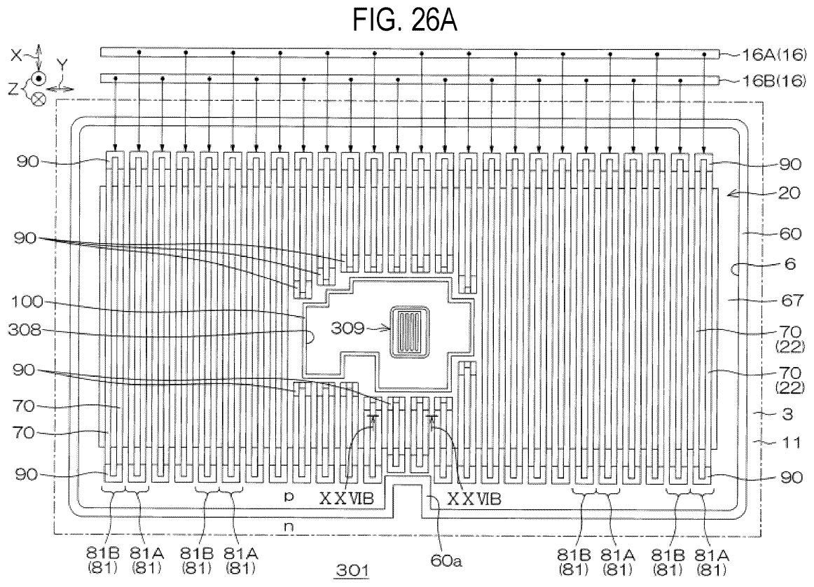

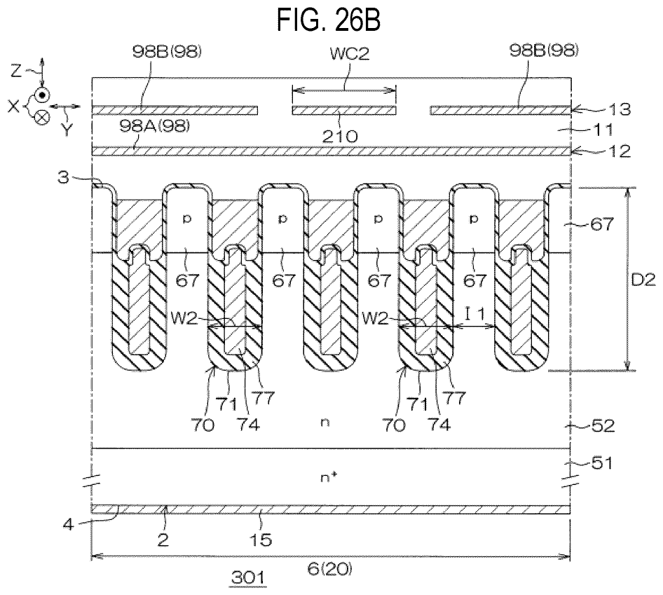

FIG. 26A is a plan view showing an output region 6 and an inner element region 308 of a semiconductor device 301 according to a third embodiment of the present disclosure, and is a view corresponding to FIG. 6. FIG. 26B is a cross-sectional view taken along line XXVIB-XXVIB shown in FIG. 26A. In the third embodiment, only the parts that are different from those of the first embodiment will be mainly described. The configurations that are the same as those described above will be designated by the same reference numerals, and the description thereof will be omitted.

The third embodiment differs from the first embodiment in that a current monitor element 309 as a first element is disposed in an inner element region 308. Moreover, the inner element region 308 is not formed in a substantially quadrangular shape, but formed in a polygonal shape (in the present embodiment, a hexadecagonal shape) having four sides parallel to the peripheral edges of the first main surface 3 in a plan view.

The current monitor element 309 according to the third embodiment has the same configuration as the current monitor element 209 according to the second embodiment. Therefore, the description of the current monitor element 309 will be omitted. The current monitor element 309 and the control circuit 23 (see FIG. 4) of the control region 7 are connected by a connection wiring 210.

Referring to FIG. 26B, the connection wiring 210 is sandwiched by a plurality of second source wirings 98B in the second direction Y. The connection wiring 210 has a wiring width WC2. The first source wiring 98A overlaps with the connection wiring 210 in the normal direction Z.

Although multiple embodiments of the present disclosure have been described above, the present disclosure may be implemented in other forms.

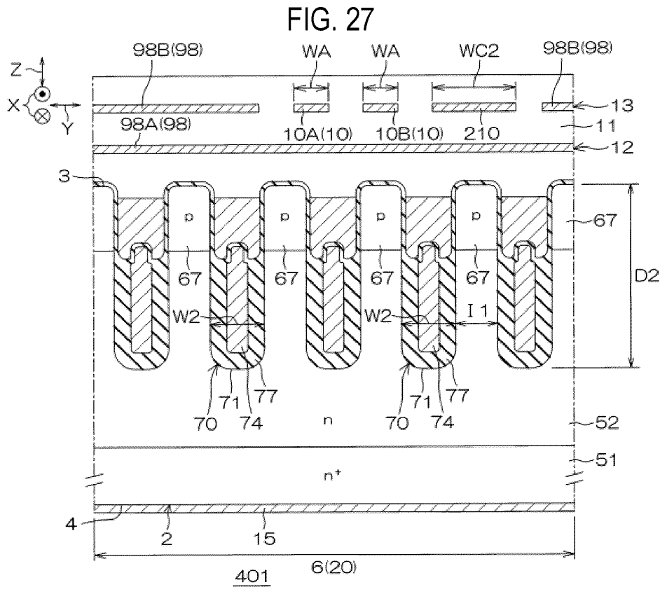

A modification of the second embodiment is shown in FIG. 27. FIG. 27 is a view corresponding to FIG. 25. The semiconductor device 401 shown in FIG. 27 differs from the second embodiment in that the wiring width WC2 of the connection wiring 210 is larger than the wiring width WA of each of the first connection wiring 10A and the second connection wiring 10B.

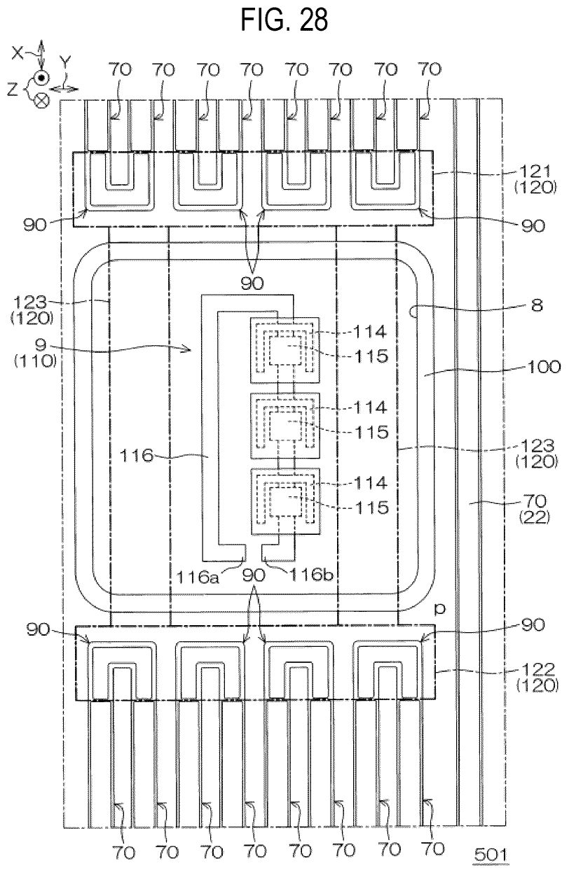

Further, a modification of the first embodiment is shown in FIG. 28. FIG. 28 is a view corresponding to FIG. 6. The semiconductor device 501 shown in FIG. 28 differs from the first embodiment in that the protrusion 8a (see FIG. 6) is not formed in the inner element region 8. In this modification, all the trench connection structures 90 facing the inner element region 8 in the first direction X are aligned in the first direction X. In this case, the protrusion 60a (see FIG. 6) may not be formed in the first trench isolation structure 60.

Further, the modification shown in FIG. 28 may be combined not only with the semiconductor device 1 of the first embodiment but also with the semiconductor devices 201 and 301 of the second and third embodiments.

Furthermore, in the first and second embodiments, instead of the temperature sensor element 9, other types of temperature sensor elements may be adopted. For example, a temperature sensor element having a configuration, in which a p-type diffusion region isolated from the surroundings is formed inside the inner element region 8 or 208 by an annular isolation structure equivalent to the third trench isolation structure 140 (see FIG. 22) and a trench gate structure is formed in the diffusion region, may be adopted.

In addition, although the temperature sensor element 9, the current monitor element 209, and the current monitor element 309 are taken as examples of the elements (the first element and the second element) arranged in the inner element region 8, 208 or 308, elements other than the temperature sensor element and the current monitor element may also be arranged in the inner element region 8, 208 or 308.

In addition, although the case where the connection wiring 10A, 10B or 210 connects the elements (the first element and the second element) arranged in the inner element region 8, 208 or 308 and the control region 7 has been described as an example, the connection wirings 10A, 10B or 210 may be connected to regions other than the control region 7.

Further, in each of the above-described embodiments, the example in which the wiring structure including the first wiring layer 12 and the second wiring layer 13 is adopted has been described. However, the wiring structure is not limited to the two-layer structure, and may be a three-layer structure or a multilayer structure in which four or more layers are laminated.

Further, in each of the above-described embodiments, there has been described the example in which the first conductivity type is n type and the second conductivity type is p type. However, the first conductivity type may be p type and the second conductivity type may be n type. A specific configuration in this case may be obtained by replacing the n-type region with a p-type region and replacing the p-type region with an n-type region in the above description and the accompanying drawings.

The above-described embodiments of the present disclosure are exemplary in all respects and should not be construed as being limitative, and are intended to include changes in all respects.

The features described below as supplementary notes can be extracted from the description of the present disclosure and drawings. Hereinafter, alphanumeric characters in parentheses represent corresponding components in the embodiments described above, but are not intended to limit the scope of each item (Clause) to the embodiments.

### [Supplementary Note 1-1]

A semiconductor device (1, 201, 301, 401 or 501) including:
a semiconductor chip (2) having a main surface (3);
an output region (6) formed over the main surface (3) with output elements being arranged in the output region;
an inner element region (8, 208 or 308) surrounded by the output region and insulated and isolated from the output region (6) with a first element (9 or 309) different from the output elements (20) being arranged in the inner element region;
a first wiring layer (12) formed over the main surface (3) so as to cover the output region (6) and including a first output wiring (98A) electrically connected to the output elements (20); and
a second wiring layer (13) formed over the first wiring layer (12) and including second output wirings (98B) electrically connected to the first output wiring (98A) and a connection wiring (10 or 210) insulated and isolated from the second output wirings (98B), the connection wiring (10 or 210) extending across the output region (6) from the inner element region (8, 208 or 308) to an outer region (7) outside the output region (6),
wherein the output elements (20) are arranged below the connection wiring (10 or 210) and include a trench electrode structure (70) overlapping with the connection wiring (10 or 210) in a thickness direction (Z) of the semiconductor chip (2).

According to the above-described configuration, the connection wiring (10 or 210) is included in the second wiring layer (13). Therefore, the first element (9 or 309) can be arranged in a region below the connection wiring (10 or 210) over the main surface (3). By arranging the first element (9 or 309) below the connection wiring (10 or 210), it is possible to enhance the mounting efficiency of the first element (9 or 309) over the main surface. This makes it possible to reduce the chip area.

### [Supplementary Note 1-2]

The semiconductor device (1, 201, 301, 401 or 501) of Supplementary Note 1-1, wherein the connection wiring (10 or 210) is sandwiched between the second output wirings (98B) in a second direction (Y) intersecting a first direction (X) in which the trench electrode structure (70) extends.

### [Supplementary Note 1-3]

The semiconductor device (1, 201, 301, 401 or 501) of Supplementary Note 1-1 or 1-2, wherein the first output wiring (98A) included in the first wiring layer (12) overlaps with the connection wiring (10 or 210) in the thickness direction (Z) of the semiconductor chip (2).

### [Supplementary Note 1-4]

The semiconductor device (1, 201, 301, 401 or 501) of any one of Supplementary Notes 1-1 to 1-3, wherein the output elements (20) include output transistors (20) formed on the main surface (3),
wherein the semiconductor device further includes an interlayer insulating layer (11) configured to cover the main surface (3),
wherein the first wiring layer (12) and the second wiring layer (13) are formed in the interlayer insulating layer (11), and
wherein each of the first output wiring (98A) and the second output wirings (98B) includes a source wiring (98A or 98B) connected to the output transistors (20).

### [Supplementary Note 1-5]

The semiconductor device (1, 201, 301, 401 or 501) of any one of Supplementary Notes 1-1 to 1-4, wherein the trench electrode structure (70) is arranged in a region of the output region (6) sandwiched between the outer region (7) and the inner element region (8, 208 or 308) in a first direction (X) in which the trench electrode structure (70) extends such that the trench electrode structure is arranged over an entire region, in a second direction intersecting the first direction, of the region of the output region (6) sandwiched between the outer region (7) and the inner element region (8, 208 or 308) in the first direction (X).

### [Supplementary Note 1-6]

The semiconductor device (1, 201, 301, 401 or 501) of Supplementary Note 1-5, wherein the output region (6) is formed in an annular shape surrounding the inner element region (8, 208 or 308), and
wherein the output elements (20) are arranged in an annular shape surrounding the inner element region (8, 208 or 308).

### [Supplementary Note 1-7]

The semiconductor device (1, 201, 301, 401 or 501) of any one of Supplementary Notes 1-1 to 1-6, further including:
an annular isolation structure (100) configured to surround the inner element region (8, 208 or 308) and insulate and isolate the inner element region (8, 208 or 308) from the output region (6).

### [Supplementary Note 1-8]

The semiconductor device (1, 201, 301, 401 or 501) of Supplementary Note 1-7, wherein the isolation structure (100) includes an isolation electrode (103) buried in an isolation trench (101) with an isolation insulator (102) interposed between the isolation electrode (103) and the isolation trench (101).

### [Supplementary Note 1-9]

The semiconductor device (201, 301 or 401) of any one of Supplementary Notes 1-1 to 1-8, wherein the connection wiring (10 or 210) includes a plurality of connection wirings (10 or 210), and
wherein at least one of the plurality of connection wirings (10 or 210) has a width (WC2) different from widths (WA) of the other connection wiring (10).

### [Supplementary Note 1-10]

The semiconductor device (1, 201, 401 or 501) of any one of Supplementary Notes 1-1 to 1-9, wherein the first element (9) includes a temperature sensor element (9) configured to detect a temperature of the output region (6).

### [Supplementary Note 1-11]

The semiconductor device (1, 201, 401 or 501) of Supplementary Note 1-10, wherein the temperature sensor element (9) includes a temperature sensing diode (110) and a diode wiring (116) configured to connect the temperature sensing diode (110) and the connection wiring (10), and
wherein the diode wiring (116) is included in the first wiring layer (12).

### [Supplementary Note 1-12]

The semiconductor device (201, 401 or 501) of any one of Supplementary Notes 1-1 to 1-11, wherein a second element (209) different from the first element (9) is further arranged in the inner element region (208).

### [Supplementary Note 1-13]

The semiconductor device (201, 401 or 501) of Supplementary Note 1-12, wherein the second element (209) includes a current monitor element (209) configured to detect an output current (Io) generated by the output elements (20).

### [Supplementary Note 1-14]

The semiconductor device (301, 401 or 501) of any one of Supplementary Notes 1-1 to 1-9, wherein the first element (309) includes a current monitor element (309) configured to detect an output current (Io) generated by the output elements (20).

### [Supplementary Note 1-15]

The semiconductor device (1, 201, 301, 401 or 501) of any one of Supplementary Notes 1-1 to 1-14, wherein the outer region (7) includes a control region (7) configured to generate a control signal.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip having a main surface;
an output region formed over the main surface with output elements being arranged in the output region;
an inner element region surrounded by the output region and insulated and isolated from the output region with a first element different from the output elements being arranged in the inner element region;
a first wiring layer formed over the main surface so as to cover the output region and including a first output wiring electrically connected to the output elements; and
a second wiring layer formed over the first wiring layer and including second output wirings electrically connected to the first output wiring and a connection wiring insulated and isolated from the second output wirings, the connection wiring extending across the output region from the inner element region to an outer region outside the output region,
wherein the output elements are arranged below the connection wiring and include a trench electrode structure overlapping with the connection wiring in a thickness direction of the semiconductor chip.

2. The semiconductor device of claim 1, wherein the connection wiring is sandwiched between the second output wirings in a second direction intersecting a first direction in which the trench electrode structure extends.

3. The semiconductor device of claim 1, wherein the first output wiring included in the first wiring layer overlaps with the connection wiring in the thickness direction of the semiconductor chip.

4. The semiconductor device of claim 1, wherein the output elements include output transistors formed on the main surface,
wherein the semiconductor device further comprises an interlayer insulating layer configured to cover the main surface,
wherein the first wiring layer and the second wiring layer are formed in the interlayer insulating layer, and
wherein each of the first output wiring and the second output wirings includes a source wiring connected to the output transistors.

5. The semiconductor device of claim 1, wherein the trench electrode structure is arranged in a region of the output region sandwiched between the outer region and the inner element region in a first direction in which the trench electrode structure extends such that the trench electrode structure is arranged over an entire region, in a second direction intersecting the first direction, of the region of the output region sandwiched between the outer region and the inner element region in the first direction.

6. The semiconductor device of claim 5, wherein the output region is formed in an annular shape surrounding the inner element region, and
wherein the output elements are arranged in an annular shape surrounding the inner element region.

7. The semiconductor device of claim 1, further comprising an annular isolation structure configured to surround the inner element region and insulate and isolate the inner element region from the output region.

8. The semiconductor device of claim 7, wherein the isolation structure includes an isolation electrode buried in an isolation trench with an isolation insulator interposed between the isolation electrode and the isolation trench.

9. The semiconductor device of claim 1, wherein the connection wiring includes a plurality of connection wirings, and
wherein at least one of the plurality of connection wirings has a width different from widths of the other connection wirings.

10. The semiconductor device of claim 1, wherein the first element includes a temperature sensor element configured to detect a temperature of the output region.

11. The semiconductor device of claim 10, wherein the temperature sensor element includes a temperature sensing diode and a diode wiring configured to connect the temperature sensing diode and the connection wiring, and
wherein the diode wiring is included in the first wiring layer.

12. The semiconductor device of claim 1, wherein a second element different from the first element is further arranged in the inner element region.

13. The semiconductor device of claim 12, wherein the second element includes a current monitor element configured to detect an output current generated by the output elements.

14. The semiconductor device of claim 1, wherein the first element includes a current monitor element configured to detect an output current generated by the output elements.

15. The semiconductor device of claim 1. wherein the outer region includes a control region configured to generate a control signal.
